(19) United States
(12) Patent Application Publication
(10) Pub. No.: US 2024/0407232 A1
(43) Pub. Date: Dec. 5, 2024

(54) DISPLAY PANEL AND METHOD FOR MANUFACTURING THE SAME, AND DISPLAY DEVICE

(71) Applicants: MIANYANG BOE OPTOELECTRONICS TECHNOLOGY CO.,LTD., Sichuan (CN); BOE TECHNOLOGY GROUP CO., LTD., Beijing (CN)

(72) Inventors: Zongqiu HANG, Beijing (CN); Congzhen HAN, Beijing (CN); Zifeng WANG, Beijing (CN); Xin WU, Beijing (CN); Xiaoge WANG, Beijing (CN); Engan YE, Beijing (CN); Yongkai WU, Beijing (CN); Liting ZHANG, Beijing (CN); Gaoqiang WANG, Beijing (CN); Quanjun WANG, Beijing (CN); Huaqiang GUO, Beijing (CN); Wen SUN, Beijing (CN); Guoren HU, Beijing (CN)

(73) Assignees: MIANYANG BOE OPTOELECTRONICS TECHNOLOGY CO.,LTD., Sichuan (CN); BOE TECHNOLOGY GROUP CO., LTD., Beijing (CN)

(21) Appl. No.: 18/262,284

(22) PCT Filed: Mar. 11, 2022
(86) PCT No.: PCT/CN2022/080409

§ 371 Date: Jul. 20, 2023

(51) Int. Cl. H10K 59/80; H10K 59/12; H10K 59/122; H10K 77/10; H10K 102/00

(52) U.S. Cl. CPC H10K 59/873; H10K 59/1201; H10K 59/122; H10K 77/111; H10K 2102/311

(57) ABSTRACT

A display panel has a display region, an opening region, and an opening peripheral region; the opening peripheral region includes a first isolation region surrounding the opening region; the display panel includes a substrate, a driving circuit layer and first isolation columns; at least one insulating layer of the driving circuit layer is located in the display region and the opening peripheral region; the first isolation columns are disposed on the at least one layer of insulating layer and located in the first isolation region; each first isolation column surrounds the opening region; the first isolation columns are arranged at intervals along a radial direction of the opening region; a portion of the at least one insulating layer located between at least two adjacent first isolation columns is provided therein with a groove; and a filling layer made of an organic material is filled in the groove.

### CROSS-REFERENCE TO RELATED APPLICATION

This application is a national phase entry under 35 USC 371 of International Patent Application No. PCT/CN2022/080409, filed on Mar. 11, 2022, which is incorporated herein by reference in its entirety.

### TECHNICAL FIELD

The present disclosure relates to the field of display technology, and in particular, to a display panel and a method for manufacturing the same, and a display device.

### BACKGROUND

In a display device, a flexible panel is usually provided therein with a groove, a hole and the like to meet an increasingly improved requirement of a screen-to-body ratio of an electronic device. A current mature technology that can make the screen-to-body ratio of the display panel high is a screen opening technology.

### SUMMARY

In one aspect, a display panel is provided. The display panel has a display region, at least one opening region, and an opening peripheral region located between the opening region and the display region; the opening peripheral region surrounds the opening region; and the opening peripheral region includes a first isolation region surrounding the opening region. The display panel includes: a substrate, a driving circuit layer disposed on a side of the substrate, and a plurality of first isolation columns disposed on a side of the at least one insulating layer away from the substrate. The substrate has an opening in the opening region. The driving circuit layer includes at least one insulating layer, and the at least one insulating layer is located in the display region and the opening peripheral region. The plurality of first isolation columns are located in the first isolation region, each first isolation column surrounds the opening region, and the plurality of first isolation columns are arranged at intervals in a radial direction of the opening region. A portion of the at least one insulating layer located between at least two adjacent first isolation columns is provided therein with a groove, and the groove surrounds the opening region; and the groove is filled with a filling layer, and a material of the filling layer is an organic material.

In some embodiments, a portion of the at least one insulating layer between every two adjacent first isolation columns is provided therein with a groove, grooves provided in the at least one insulating layer include first grooves and second grooves, a dimension of a first groove of the first grooves in a first direction is greater than a dimension of a second groove of the second grooves in the first direction, and the first direction is perpendicular to the substrate.

In some embodiments, the first grooves and the second grooves are alternately arranged in the radial direction of the opening region.

In some embodiments, the dimension of the first groove in the first direction is in a range from 1.4 μm to 1.6 μm; and the dimension of the second groove in the first direction is in a range from 0.7 μm to 0.8 μm.

In some embodiments, the substrate includes a barrier layer and a buffer layer that are stacked; the at least one insulating layer includes a first insulating layer, a second insulating layer, and an interlayer dielectric layer; the first insulating layer is disposed on a side of the buffer layer away from the barrier layer, the second insulating layer is disposed on a side of the first insulating layer away from the barrier layer, and the interlayer dielectric layer is disposed on a side of the second insulating layer away from the barrier layer; the first grooves reach the barrier layer, and the first grooves penetrate into the barrier layer; and the second grooves reach the buffer layer.

In some embodiments, a thickness of a portion, penetrated by the first groove, of the barrier layer in the first direction is a half of a thickness of the barrier layer in the first direction.

In some embodiments, a dimension of an opening of the groove in a second direction is ⅓ to ⅔ of a distance, in the second direction, between two adjacent first isolation columns with the groove therebetween. The second direction is the radial direction of the opening region.

In some embodiments, the driving circuit layer further includes a first planarization layer and a second planarization layer; the first planarization layer is disposed on the side of the at least one insulating layer away from the substrate, and the second planarization layer is disposed on a side of the first planarization layer away from the substrate; a filling layer in the first groove includes a first filling layer and a second filling layer, and a filling layer in the second groove includes a second filling layer; and the first filling layer and the first planarization layer are arranged in a same layer, and the second filling layer in the first groove, the second filling layer in the second groove, and the second planarization layer are arranged in a same layer.

In some embodiments, the opening peripheral region further includes a first encapsulation dam region and a second isolation region; the first encapsulation dam region is located between the first isolation region and the display region, and surrounds the first isolation region; the second isolation region is located between the first encapsulation dam region and the display region, and surrounds the first encapsulation dam region; the first encapsulation dam region is provided therein with at least one first encapsulation dam, the at least one first encapsulation dam surrounds the opening region, and the at least one first encapsulation dam is disposed on the side of the at least one insulating layer away from the substrate; the second isolation region is provided therein with a plurality of second isolation columns, each second isolation column surrounds the opening region, and the plurality of second isolation columns are arranged at intervals in the radial direction of the opening region.

In some embodiments, a portion of the at least one insulating layer between two adjacent second isolation columns is provided therein with a depression portion.

In some embodiments, the opening peripheral region includes two first isolation regions, the two first isolation regions are respectively a first isolation sub-region and a second isolation sub-region, the first isolation sub-region and the second isolation sub-region are arranged at intervals in the radial direction of the opening region, and the second isolation sub-region is closer to the opening region than the first isolation sub-region. The display panel further includes a light-emitting device layer, a first inorganic encapsulation film layer, an organic encapsulation film layer, and a second inorganic encapsulation film layer. The light-emitting device layer is disposed on a side of the driving circuit layer away from the substrate, and the light-emitting device layer is located in the display region and the opening peripheral region. The first inorganic encapsulation film layer is disposed on a side of the light-emitting device layer away from the substrate, and the first inorganic encapsulation film layer is located in the display region and the opening peripheral region. The organic encapsulation film layer is disposed on a side of the first inorganic encapsulation film layer away from the substrate, and the organic encapsulation film layer is located in the display region, the second isolation region and the first isolation sub-region. The second inorganic encapsulation film layer is disposed on a side of the organic encapsulation film layer away from the substrate, and the second inorganic encapsulation film layer is located in the display region and the opening peripheral region.

In some embodiments, the driving circuit layer further includes a first gate layer, a second gate layer, a first source-drain metal layer and a second source-drain metal layer; the at least one insulating layer includes a first insulating layer, a second insulating layer, and an interlayer dielectric layer; the first gate layer is disposed on a side of the first insulating layer away from the substrate; the second insulating layer is disposed on a side of the first gate layer away from the substrate; the second gate layer is disposed on a side of the second insulating layer away from the substrate; the interlayer dielectric layer is disposed on a side of the second gate layer away from the substrate; the first source-drain metal layer is disposed on a side of the interlayer dielectric layer away from the substrate; the first planarization layer is disposed on a side of the first source-drain metal layer away from the substrate; the second source-drain metal layer is disposed on a side of the first planarization layer away from the substrate; and the second planarization layer is disposed on a side of the second source-drain metal layer away from the substrate. The display panel further includes second isolation columns, the first isolation columns and the second isolation columns are arranged in a same layer as the second source-drain metal layer.

In some embodiments, a region between the first isolation sub-region and the second isolation sub-region is a second encapsulation dam region; the second encapsulation dam region is provided therein with at least one second encapsulation dam, the at least one second encapsulation dam surrounds the opening region, and the at least one second encapsulation dam is disposed on a side of the driving circuit layer away from the substrate.

In some embodiments, a thickness of the first encapsulation dam in the first direction is greater than a thickness of the second encapsulation dam in the first direction.

In some embodiments, the light-emitting device layer includes a pixel defining layer. The first encapsulation dam includes a first portion, a second portion and a third portion; the first portion and the first planarization layer are arranged in a same layer; the second portion is disposed on a side of the first portion away from the substrate, and the second portion and the second planarization layer are arranged in a same layer; and the third portion is disposed on a side of the second portion away from the substrate, and the third portion and the pixel defining layer are arranged in a same layer. The second encapsulation dam includes a third portion arranged in a same layer as the pixel defining layer.

In some embodiments, the first isolation region is provided therein with a plurality of first patterns and a plurality of second patterns, the plurality of first patterns are located in the first gate layer, and the plurality of second patterns are located in the second gate layer; each first pattern surrounds the opening region, and each second pattern surrounds the opening region; and orthographic projections, on the substrate, of the first isolation column, the first pattern, and the second pattern have a common overlapping region.

In some embodiments, the display panel further includes an inorganic insulating layer and an organic cover layer; the inorganic insulating layer is disposed on a side of the second inorganic encapsulation film layer away from the substrate, and is located in the display region and the opening peripheral region; and the organic cover layer is disposed on a side of the inorganic insulating layer away from the substrate, and is located in the display region and the opening peripheral region.

In another aspect, a method for manufacturing a display panel is provided. The method for manufacturing the display panel includes: forming a substrate, the substrate having a display region, at least one opening region and an opening peripheral region located between the opening region and the display region, the opening peripheral region surrounding the opening region, the substrate having an opening in the opening region, the opening peripheral region including a first isolation region surrounding the opening region; and

forming a driving circuit layer on the substrate, the driving circuit layer including at least one insulating layer located in the display region and the opening peripheral region; forming at least one groove on the at least one insulating layer in the first isolation region, the at least one groove surrounding the opening region; forming a filling layer in the at least one groove, a material of the filling layer being an organic material; and forming first isolation columns on two sides of each groove in a radial direction of the opening region, the first isolation columns being located in the first isolation region, the first isolation columns surrounding the opening region.

In some embodiments, the step of forming the at least one groove on the at least one insulating layer in the first isolation region includes; forming a plurality of grooves in the at least one insulating layer in the first isolation region, the plurality of grooves including first grooves and second grooves that are arranged alternately in the radial direction of the opening region. The step of forming the plurality of grooves in the at least one insulating layer in the first isolation region includes: forming a plurality of third grooves in the at least one insulating layer in the first isolation region, the plurality of third grooves surrounding the opening region, the plurality of third grooves being arranged at intervals along the radial direction of the opening region, and among the plurality of third grooves, every other third groove being selected as a target groove; and forming a fourth groove in each target groove. The fourth groove and the target groove in which the fourth groove is located form a first groove. Among the plurality of third grooves, third grooves that are not selected as target grooves form the second grooves.

The step of forming the filling layer in the at least one groove includes: forming a first filling layer and a second filling layer in the first groove, and forming a second filling layer in a second groove, including: forming a first planarization layer on a side of the at least one insulating layer away from the substrate, a portion of the first planarization layer forming a first filling layer in the first groove; and forming a second planarization layer on a side of the first planarization layer away from the substrate, portions of the second planarization layer forming a second filling layer in the first groove and a second filling layer in the second groove.

In some embodiments, the step of forming the substrate includes: dividing the opening peripheral region into two first isolation regions, the two first isolation regions being respectively a first isolation sub-region and a second isolation sub-region, the first isolation sub-region and the second isolation sub-region being arranged at intervals in the radial direction of the opening region, the second isolation sub-region being closer to the opening region than the first isolation sub-region, and a region between the first isolation sub-region and the second isolation sub-region being a second encapsulation dam region;

dividing a region, located between the display region and the first isolation sub-region, of the opening peripheral region into a second isolation region and a first encapsulation dam region, the second isolation region and the first encapsulation dam region surrounding the opening region, and the first encapsulation dam region being closer to the first isolation region than the second isolation region.

The method for manufacturing the display panel further includes: forming a light-emitting device layer on a side of the driving circuit layer away from the substrate, the light-emitting device layer being located in the display region and the opening peripheral region; forming a first inorganic encapsulation film layer on a side of the light-emitting device layer away from the substrate, the first inorganic encapsulation film layer being located in the display region and the opening peripheral region; forming an organic encapsulation film layer on a side of the first inorganic encapsulation film layer away from the substrate, the organic encapsulation film layer being located in the display region, the second isolation region and the first isolation sub-region; forming a second inorganic encapsulation film layer on a side of the organic encapsulation film layer away from the substrate, the second inorganic encapsulation film layer being located in the display region and the opening peripheral region; and

forming an inorganic insulating layer on a side of the second inorganic encapsulation film layer away from the substrate, the inorganic insulating layer being located in the display region and the opening peripheral region; and forming an organic cover layer on a side of the inorganic insulating layer away from the substrate, the organic cover layer being located in the display region and the opening peripheral region.

In yet another aspect, a display device is provided. The display device includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel, in accordance with some embodiments;

FIG. 2 is an enlarged view of a region K of the display panel shown in FIG. 1, in accordance with some embodiments;

FIG. 3 is a sectional view of the display panel shown in FIG. 2 taken along the line M-M, in accordance with some embodiments;

FIG. 4 is a structural diagram of a display panel, in accordance with some embodiments of the present disclosure;

FIG. 5 is an enlarged view of a region O of the display panel shown in FIG. 4, in accordance with some embodiments of the present disclosure;

FIG. 6 is a sectional view of the display panel shown in FIG. 5 taken along the line N-N, in accordance with some embodiments of the present disclosure;

FIG. 7A is an enlarged view of a region P of the display panel shown in FIG. 6, in accordance with some embodiments of the present disclosure;

FIG. 7B is an enlarged view of a region P′ of the display panel shown in FIG. 7A, in accordance with some embodiments of the present disclosure;

FIGS. 8 and 9 are structural diagrams of another display panel, in accordance with some embodiments;

FIG. 10 is an enlarged view of a region R of the display panel shown in FIG. 9, in accordance with some embodiments;

FIG. 11 is a structural diagram of another display panel, in accordance with some embodiments of the present disclosure;

FIG. 12 is a sectional view of the display panel shown in FIG. 11 taken along the line S-S, in accordance with some embodiments of the present disclosure;

FIG. 13 is an enlarged view of a region T of the display panel shown in FIG. 12, in accordance with some embodiments of the present disclosure;

FIG. 14 is a flow diagram of a method for manufacturing a display panel, in accordance with some embodiments of the present disclosure;

FIGS. 15 to 21 are diagrams showing steps of a method for manufacturing a display panel, in accordance with some embodiments of the present disclosure;

FIG. 22 is a flow diagram of a method for manufacturing a display panel, in accordance with some embodiments of the present disclosure;

FIG. 23 is a diagram showing a step of a method for manufacturing a display panel, in accordance with some embodiments of the present disclosure;

FIG. 24 is a diagram showing step S1 of a method for manufacturing a display panel, in accordance with some embodiments of the present disclosure;

FIGS. 25 to 28 are diagrams showing steps of a method for manufacturing a display panel, in accordance with some embodiments of the present disclosure; and

FIG. 29 is a structural diagram of a display device, in accordance with some embodiments of the present disclosure.

### DETAILED DESCRIPTION

The technical solutions in embodiments of the present disclosure will be described clearly and completely in combination with the accompanying drawings. However, the described embodiments are merely some but not all of the embodiments of the present disclosure. All other embodiments obtained by a person having ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in an open and inclusive meaning, i.e., “including, but not limited to”. In the description of the specification, the terms such as “one embodiment,” “some embodiments,” “exemplary embodiments,” “example.” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are only used for descriptive purposes, and are not to be construed as indicating or implying relative importance or implicitly indicating the number of indicated technical features. Thus, a feature defined with the term such as “first” or “second” may explicitly or implicitly include one or more features. In the description of the embodiments of the present disclosure, the terms “a plurality of”, “the plurality of” and “multiple” each mean two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if”, depending on the context, is optionally construed as “when” or “in a case where” or “in response to determining” or “in response to detecting”. Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

The phase “applicable to” or “configured to” as used herein indicates an open and inclusive expression, which does not exclude devices that are applicable to or configured to perform additional tasks or steps.

In addition, the phrase “based on” used is meant to be open and inclusive, since processes, steps, calculations or other actions “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The terms such as “parallel”, “perpendicular” or “equal” as used herein include a stated case and a case similar to the stated case. The similar case is within an acceptable range of deviation, and the acceptable range of deviation is determined by a person of ordinary skill in the art in view of measurement in question and errors associated with measurement of a particular quantity (i.e., limitations of a measurement system). For example, the term “parallel” includes absolute parallelism and approximate parallelism, where an acceptable range of deviation of the approximate parallelism may be, for example, a deviation within 5 degrees; the term “perpendicular” includes absolute perpendicularity and approximate perpendicularity, where an acceptable range of deviation of the approximate perpendicularity may also be, for example, a deviation within 5 degrees. The term “equal” includes absolute equality and approximate equality, where an acceptable range of deviation of the approximate equality may be, for example, a difference between two equals of less than or equal to 5% of either of the two equals.

It will be understood that, in a case where a layer or component is referred to as being on another layer or a substrate, it may be that the layer or component is directly on the another layer or substrate; or it may be that intermediate layer(s) exist between the layer or component and the another layer or substrate.

Exemplary embodiments are described herein with reference to sectional views and/or plan views as idealized exemplary drawings. In the accompanying drawings, thickness of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but as including shape deviations due to, for example, manufacturing. For example, an etched region shown to have a rectangular shape generally has a feature of being curved. Thus, the regions shown in the accompanying drawings are schematic in nature, and their shapes are not intended to show actual shapes of regions in a device, and are not intended to limit the scope of the exemplary embodiments.

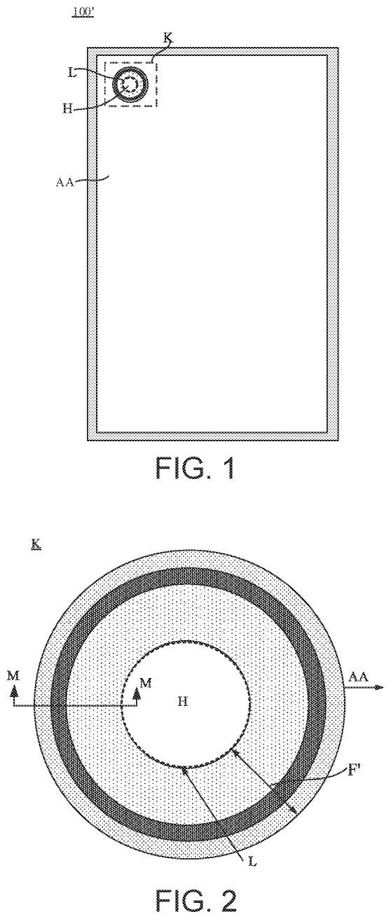

Generally, a display device includes a display panel, and further includes other electrical component(s), such as a camera. The electrical component may be arranged in a bezel region of the display panel, which will cause an overall area of the bezel region to be increased, which in turn affects a screen-to-body ratio of the display panel. As shown in FIG. 1, a display region (active area, AA) of the display panel 100′ is provided therein with an opening, and the electrical component is arranged in the opening, the area of the bezel region is not increased. In addition, an area of the opening is generally small, thereby improving the screen-to-body ratio of the display panel 100′. However, an electroluminescent (EL) film layer (including a light-emitting layer, a cathode layer, an optical adjustment layer, and the like) is provided at a position of the opening in the display region AA of the display panel. At present, the EL film layer is blocked by mainly using a solution such as an isolation column or an isolation groove, and then an encapsulation is performed on an opening peripheral region by a chemical vapor deposition (CVD) to isolate water vapor.

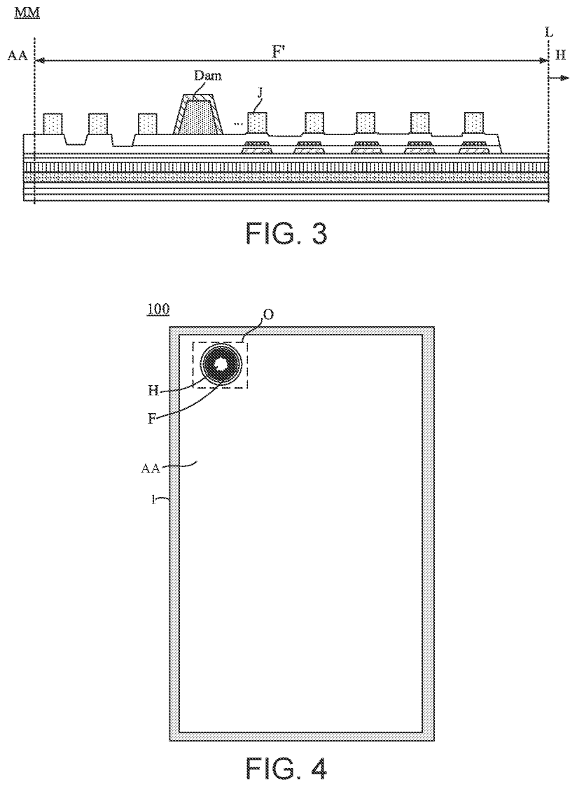

In some examples, as shown in FIGS. 2 and 3, a region between the display region AA and an opening region H is the opening peripheral region F′. In order to improve the encapsulation ability of the opening peripheral region F′, an encapsulation dam Dam or/and an isolation column J are generally provided in the opening peripheral region F′. In order to further improve the screen-to-body ratio of the display panel 100′, there are mainly the following solutions in the related art: (1) the number of dams Dam is reduced to the maximum extent, and a structure of a single encapsulation dam Dam is adopted; (2) display region dummy pixels (AA dummy pixels) around the opening peripheral region F′ is reduced; (3) the number of isolation columns J outside the encapsulation dam Dam is reduced; (4) a width of a wiring region on a periphery of the opening is reduced.

The inventors have found that the above technical solutions are all designed by adjusting the structural design of the opening peripheral region F′ to reduce the size of the opening peripheral region F′, so as to achieve the purpose of improving the screen-to-body ratio of the display panel. In this way, there may cause some problems; especially, the solution (3) where the number of isolation columns J outside the encapsulation dam Dam is reduced may cause the following problems. The isolation columns J outside the encapsulation dam Dam is the first defense line closest to the opening cutting edge line L; therefore, if the number and the width of the isolation columns J are reduced, in the cutting process of forming the opening by laser, the film layer close to the position of the encapsulation dam Dam will be easily affected by the laser cutting heat, which leads to failure of the encapsulation structure of the whole opening peripheral region F′. For example, the crack or peeling of the film layer may be caused, resulting in the intrusion of water vapor and the erosion of the film layer. As a result, the GDS exists in the inspection of the electron microscope, which leads to the encapsulation failure of the opening peripheral region F′ and reduces the service life of the product.

Therefore, in order to improve the screen-to-body ratio of the display panel and achieve the narrow design of the opening peripheral region F′, the requirement for the encapsulation ability of the opening peripheral region F′ is high; and in order to avoid the encapsulation failure, the encapsulation ability of the opening peripheral region of the display panel needs to be increased. The peeling of the film layer is avoided, and the crack is prevented from extending to the display region AA.

The inventors have also found that in an OLED (Organic light-emitting Diode) film layer structure, due to the material characteristics of the inorganic film layer, compared to the organic film layer, the inorganic film layer is more easy to have the problem of stress concentration or heat stress that causes the crack of the film layer. According to the structural design of the opening peripheral region, once a crack occurs in the inorganic film layer, the crack extends to the display region AA, causing film layers in the display region to be damaged by the erosion of water vapor.

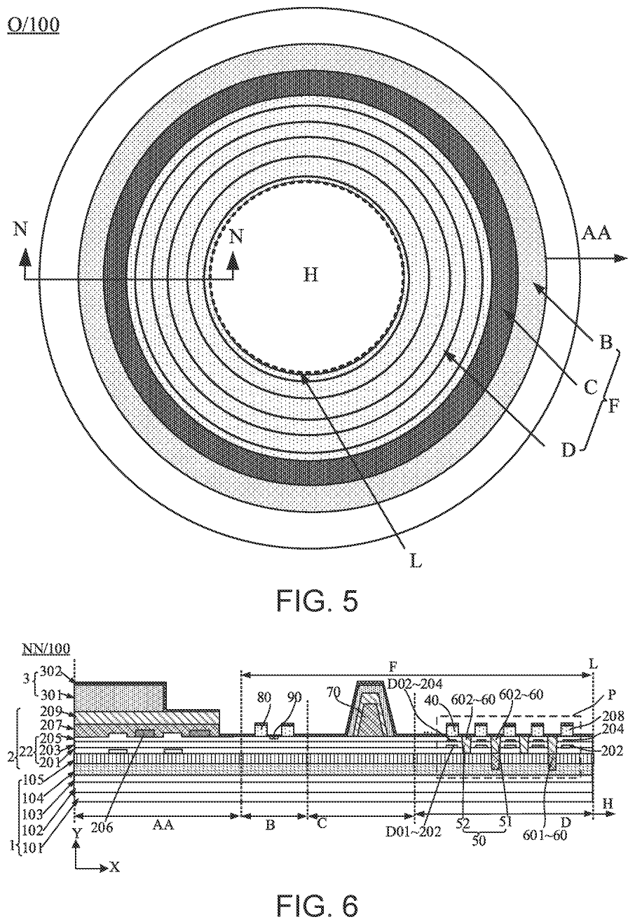

Based on this, a first aspect of the present disclosure provides a display panel 100. As shown in FIGS. 4 and 5, the display panel 100 has a display region AA, at least one opening region H, and an opening peripheral region F located between the opening region H and the display region AA, and the opening peripheral region F surrounds the opening region H. The opening peripheral region F includes a first isolation region D, and the first isolation region D surrounds the opening region H.

In some examples, referring to FIG. 4 again, the display panel 100 has an opening region H, and a shape of the opening region H is, for example, a circle. A region between the opening region H and the display region AA is an opening peripheral region F. The description that the opening peripheral region F surrounds the opening region H refers to that, the opening peripheral region F is arranged around the opening region H in a circle, and the display region AA surrounds the opening peripheral region F and the opening region H. There may be a plurality of opening regions H, and an opening peripheral region F is arranged on an outside of each opening region H and surrounds the opening region H. The number of the opening regions H is set according to needs, which is not limited here.

There may be one or more first isolation regions D included in the opening peripheral region F, which is not limited here. As for the arrangement of a plurality of first isolation regions D, reference can be made to the following contents, and details will not be provided here.

The description that the first isolation region D surrounds the opening region H refers to that the first isolation region D is arranged around the opening region H in a circle.

In some embodiments, as shown in FIG. 6, the display panel 100 includes a substrate 1 and a driving circuit layer 2 disposed on a side of the substrate 1. The substrate 1 has an opening in the opening region H. The driving circuit layer 2 includes at least one insulating layer 22, and the at least one insulating layer 22 is located in the display region AA and the opening peripheral region F. The display panel 100 further includes a plurality of first isolation columns 40 disposed on a side of the at least one insulating layer 22 away from the substrate 1. The plurality of first isolation columns 40 are located in the first isolation region D, each first isolation column 40 surrounds the opening region H, and the plurality of first isolation columns 40 are arranged at intervals in a radial direction of the opening region H. A portion of the at least one insulating layer 22 located between at least two adjacent first isolation columns 40 is provided therein with a groove 50, and the groove 50 surrounds the opening region H. The groove 50 is filled with a filling layer 60, and the filling layer 60 is made of an organic material.

The substrate 1 may be a single-layer structure or a multi-layer structure. For example, as shown in FIG. 6, the substrate 1 may include a first flexible base layer 101, a first barrier layer 102, a second flexible base layer 103, a second barrier layer 104, and a buffer layer 105 that are stacked in sequence. Materials of flexible base layers (including the first flexible base layer 101 and the second flexible base layer 103) may each include polyimide, and materials of the first barrier layer 102 and the second barrier layer 104 may each include silicon nitride and/or silicon oxide, thereby realizing the effects of blocking water and oxygen and blocking alkaline ions.

In some examples, referring to FIG. 4 again, the substrate 1 has an opening in the opening region H, an electrical component (e.g., an optical sensor) may be placed at the opening of the display panel 100. Therefore, the opening in the opening region H may penetrate through the substrate 1, which results in high light transmittance.

For example, the at least one insulating layer 22 of the driving circuit layer 2 may include a gate insulating layer and an interlayer dielectric layer; and a material of the at least one insulating layer may include silicon nitride (SiNₓ), silicon oxide (SiOₓ), silicon oxynitride (SiNₓO_{y}), or other suitable materials. It can be understood that the at least one insulating layer 22 also has an opening at the opening of the substrate 1.

Referring to FIGS. 5 and 6 again, the display panel 100 includes the first isolation region D, and further includes the plurality of first isolation columns 40 disposed in the first isolation region D, and the plurality of first isolation columns 40 that are arranged at intervals in the radial direction of the opening region H are each arranged around the opening region H in a circle. That is, the plurality of first isolation columns 40 are each a ring structure surrounding the opening region H, and diameters of the plurality of first isolation columns 40 are sequentially increased.

As shown in FIGS. 5 and 6, a portion of the at least one insulation layer 22 located between the two adjacent first isolation columns 40 is provided therein with a groove 50, and the groove 50 is arranged around the opening region H. From a top view of the display panel 100, the groove 50 is in a shape of a ring, and the groove 50 is filled with an organic material. For example, the organic material may include polyimide (PI), polyamide (PA), etc.

In the present disclosure, a groove 50 is arranged between adjacent first isolation columns 40, and a portion of the inorganic material of the at least one insulating layer 22 is removed to form the groove 50. Therefore, a volume occupied by an inorganic film layer of the at least one insulating layer 22 in the first isolation region D is reduced. That is, a volume of an inorganic film layer provided in the first isolation region D is reduced. As a result, a probability of crack in the inorganic film layer in a cutting process of the opening is reduced. The organic material is filled in the groove 50, the organic material has good ductility, which avoids stress concentration and makes the ability to resist thermal stress strong, and in turn reduce the probability of crack in the display panel 100. In a case where the inorganic film layer of the at least one layer of insulating layer 22 is cracked in the opening peripheral region F, the organic material may effectively prevent the crack from extending toward the display region AA of the display panel 100. That is, during the process of forming the opening, in a case where the opening is formed by performing, by layer, cutting at the cutting line L, due to the influence of the laser cutting heat, the crack in the opening peripheral region F may be cut off at the organic material filled in the groove 50, the crack does not extend further in the organic material. The organic material has the effect of blocking the crack, thereby effectively preventing the crack from extending to the display region AA of the display panel 100, and improving the yield of the product.

In addition, since the groove 50 is filled with the organic material, it may be possible to avoid a residual of a photoresist or a metal material in the groove 50 during a manufacturing process of the display panel 100, and in turn prevent the residual of the photoresist or the metal material in the groove 50 from reducing the effect of blocking the crack. Moreover, through the groove 50 filled with the organic material, the flatness of film layers of the display panel 100 may be improved, the encapsulation ability of the opening peripheral region F of the display panel 100 is improved, and the structure defect is avoided.

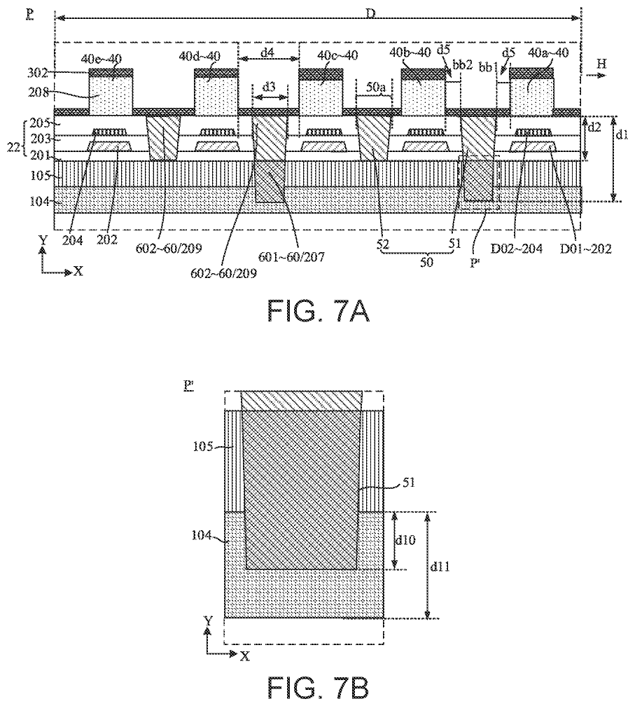

In some embodiments, as shown in FIG. 7A, a portion of the at least one insulating layer 22 located between every two adjacent first isolation columns 40 is provided therein with a groove 50. Grooves 50 provided in the at least one insulating layer 22 include first grooves 51 and second grooves 52. A dimension d1 of the first groove 51 in a first direction Y is greater than a dimension d2 of the second groove 52 in the first direction Y, that is, d1>d2. The first direction Y is perpendicular to the substrate 1.

The dimension d1 of the first groove 51 in the first direction Y is relatively large, that is, the first groove 51 is relatively deep. Therefore, a depth of an organic material that may be filled in the first groove 51 is larger, and the first groove 51 may better prevent the crack from extending to the display region AA. The dimension d2 of the second groove 52 in the first direction Y is smaller than the dimension d1 of the first groove 51, the second groove 52 is relatively shallow, so that a small amount of an inorganic material of the at least one insulating layer 22 is removed to form the second groove 52. Therefore, the second groove 52 may not only prevent the crack from extending to the display region AA, but also ensure the support ability of the at least one insulating layer 22 for the display panel, so as to ensure the structural stability of the display panel. Therefore, in the opening peripheral region F of the display panel 100, the dimension d1 of the first groove 51 in the first direction Y is greater than the dimension d2 of the second groove 52 in the first direction Y, so that the opening peripheral region F of the display panel 100 prevents the crack from extending to the display region AA, and has a good structural stability.

In some embodiments, as shown in FIG. 7A, the first grooves 51 and the second grooves 52 are alternately arranged in the radial direction of the opening region H.

In some examples, the second grooves 52 may be formed synchronously with a process for forming holes in the display region for circuit connection and/or a first process for forming grooves in a bending region of the display panel. The first grooves 51 may be formed synchronously with the process of forming the second grooves 52 and/or the process for forming holes in the display region for circuit connection and/or the first process for forming grooves in the bending region of the display panel and a second process for forming grooves in the bending region of the display panel.

For example, as shown in FIG. 7A, five first isolation columns 40 arranged at intervals in the radial direction of the opening region of the first isolation region D are respectively a first isolation column 40a, a first isolation column 40b, a first isolation column 40c, a first isolation column 40d and a first isolation column 40e. The first isolation column 40a, the first isolation column 40b, the first isolation column 40c, the first isolation column 40d and the first isolation column 40e are arranged at intervals in the radial direction gradually away from the hole region H. That is, diameters of ring structures of the first isolation column 40a, the first isolation column 40b, the first isolation column 40c, the first isolation column 40d and the first isolation column 40e gradually increase.

Grooves 50 are respectively arranged between the first isolation column 40a and the first isolation column 40b, between the first isolation column 40b and the first isolation column 40c, between the first isolation column 40c and the first isolation column 40d, and between the first isolation column 40d and the first isolation column 40e. In addition, for example, a first groove 51 may be arranged between the first isolation column 40a and the first isolation column 40b, a second groove 52 is arranged between the first isolation column 40b and the first isolation column 40c, a first groove 51 is arranged between the first isolation column 40c and the first isolation column 40d, and a second groove 52 is arranged between the first isolation column 40d and the first isolation column 40e. Thus, a structure of the first grooves 51 and the second grooves 52 arranged alternately in the radial direction of the opening region H is formed.

It can be understood that a second groove 52 may be arranged between the first isolation column 40a and the first isolation column 40b, a first groove 51 is arranged between the first isolation column 40b and the first isolation column 40c, a second groove 52 is arranged between the first isolation column 40c and the first isolation column 40d, and a first groove 51 is arranged between the first isolation column 40d and the first isolation column 40e, which is not limited here, as long as the structure of the first grooves 51 and the second grooves 52 arranged alternately in the radial direction of the opening region H is formed.

In some examples, every two adjacent first grooves 51 are in a group, every two adjacent second grooves 52 are in a group, and a group of first grooves 51 and a group of second grooves 52 are alternately arranged. Alternatively, every three adjacent first grooves 51 are in a group, every three adjacent second grooves 52 are in a group, and a group of first grooves 51 and a group of second grooves 52 are alternately arranged, which is not limited here.

In some examples, a plurality of first grooves 51 and a plurality of second grooves 52 may not be alternately arranged. For example, the plurality of first grooves 51 are close to the opening region H with respect to the plurality of second grooves 52, or the plurality of second grooves 52 are close to the opening region H with respect to the plurality of first grooves 51, which is not limited here.

In some examples, only the second grooves 52 may be provided, and as for details, reference may be made to the following content (the structure shown in FIG. 18), and details are not provided here.

In some embodiments, as shown in FIG. 7A, the dimension d1 of the first groove 51 in the first direction Y is in a range from 1.4 μm to 1.6 μm. The dimension d2 of the second groove 52 in the first direction Y is in a range from 0.7 μm to 0.8 μm.

The dimension d1 of the first groove 51 in the first direction Y, i.e., the depth of the first groove 51, is in a range from 1.4 μm to 1.6 μm. For example, the depth of the first groove 51 is 1.4 μm, 1.5 μm, or 1.6 μm, which is not limited here.

The dimension d2 of the second groove 52 in the first direction Y, i.e., the depth of the second groove 52, is in a range from 0.7 μm to 0.8 μm. For example, the depth of the second groove 52 is 0.7 μm, 0.75 μm, or 0.8 μm, which is not limited here.

In some embodiments, as shown in FIGS. 6 and 7A, the substrate 1 includes a barrier layer 104 and a buffer layer 105 that are stacked. The at least one insulating layer 22 includes a first insulating layer 201, a second insulating layer 203 and an interlayer dielectric layer 205. The first insulating layer 201 is disposed on a side of the buffer layer 105 away from the barrier layer 104, the second insulating layer 203 is disposed on a side of the first insulating layer 201 away from the barrier layer 104, and the interlayer dielectric layer 205 is disposed on a side of the second insulating layer 203 away from the barrier layer 104. The first grooves 51 reach the barrier layer 104, and the first grooves 51 penetrate into the barrier layer 104. The second grooves 52 reach the buffer layer 105.

It should be noted that the barrier layer 104 here refers to the second barrier layer 104.

The description “reach a certain film layer” means that a groove reaches the certain film layer to expose a surface of the certain film layer. For example, the second groove 52 reaches the buffer layer 105, which means that the second groove 52 penetrates through stacked film layers on the buffer layer 105 to expose a surface of the buffer layer 105. The description “penetrate into a certain film layer” here means that a groove extends into the film layer, and does not penetrate through the film layer. For example, the description that “the first grooves 51 penetrate into the barrier layer 104” means that the first grooves 51 extend into the barrier layer 104 and do not completely penetrate through the barrier layer 104.

In some examples, as shown in FIG. 7A, the second barrier layer 104, the buffer layer 105, the first insulating layer 201, the second insulating layer 203, and the interlayer dielectric layer 205 are stacked in the first direction Y. The first groove 51 penetrates through the interlayer dielectric layer 205, the second insulating layer 203, the first insulating layer 201 and the buffer layer 105, and the first groove 51 further penetrates into the second barrier layer 104. That is, the first groove 51 extends into the second barrier layer 104. The second groove 52 penetrates through the interlayer dielectric layer 205, the second insulating layer 203 and the first insulating layer 201, and the second groove 52 exposes the surface of the buffer layer 105 in a case where other film layers are not filled into the formed second groove 52.

In some embodiments, as shown in FIG. 7B, a thickness d10 of a portion 104a, which is penetrated by the first groove 51, of the barrier layer 104 in the first direction Y is a half (½) of a thickness d11 of the second barrier layer 104 in the first direction Y, that is, d10=d11×½.

Similarly, the barrier layer 104 here refers to the second barrier layer 104.

In some examples, as shown in FIG. 7B, a depth of a portion of the first groove 51 extending into the second barrier layer 104 is a half of the thickness of the second barrier layer 104. Here, the half of the thickness is an approximate value of the thickness, which is not limited to the thickness.

Since the first groove 51 extends into the second barrier layer 104, it may be possible to effectively prevent the crack from extending to the display region AA, avoid growing dark spot (GDS), and improve the yield of the product.

In some embodiments, referring to FIG. 7A again, a dimension d3 of an opening 50a of a groove 50 in a second direction X is one-third to two-thirds (⅓ to ⅔) of a distance d4, in the second direction X, between two adjacent first isolation columns 40 with the groove 50 therebetween. The second direction X is the radial direction of the opening region.

In some examples, as shown in FIG. 7A, the grooves 50 include first grooves 51 and second grooves 52, and dimensions d3 of openings 50a of the first groove 51 and the second groove 52 in the second direction X are each ⅓/, ½, or ⅔ of a distance d4 between two first isolation columns 40 in the second direction X, which is not limited here.

It can be understood that, since the dimension d3 of the opening 50a of the groove 50 in the second direction X is ⅓ to ⅔ of the distance d4, in the second direction X, between the two adjacent first isolation columns 40 with the groove 50 therebetween, gaps may exit between the groove 50 and the first isolation columns 40, which prevents the groove 50 from affecting the formation of the first isolation columns 40 located on two sides of the groove 50. For example, in a case where the groove is formed in the at least one insulating layer and is not filled, during the process of forming the isolation column, since the groove 50 is close to a target position of the first isolation column 40, a film layer at a peripheral of the target position of the first isolation column 40 is uneven, and the formed first isolation column may be inclined and collapse. In addition, distances d5 of an edge of the opening 50a of the groove 50 to adjacent first isolation columns 40 may be set to be approximately equal. For example, as shown in FIG. 7A, a first groove 51 is arranged between the first isolation column 40a and the first isolation column 40b, and an opening 50a of the first groove 51 has two edges in the radial direction of the opening region H (the second direction X), which are an edge bb1 and an edge bb2. A distance d5 between the edge bb1 and an adjacent first isolation column 40a in the second direction X is approximately equal to a distance d5 between the edge bb2 and an adjacent first isolation column 40b. In this way, it may further prevent the groove 50 from affecting the formation of the first isolation columns 40b on the two sides of the groove 50.

In some embodiments, as shown in FIGS. 6 and 7A, the driving circuit layer 2 further includes a first planarization layer 207 and a second planarization layer 209, the first planarization layer 207 is disposed on the side of the at least one insulating layer 22 away from the substrate 1, and the second planarization layer 209 is disposed on a side of the first planarization layer 207 away from the substrate 1. A filling layer 60 in the first groove 51 includes a first filling layer 601 and a second filling layer 602, and a filling layer 60 in the second groove 52 includes a second filling layer 602. The first filling layer 601 and the first planarization layer 207 are arranged in the same layer, and the second filling layers 602 and the second planarization layer 209 are arranged in the same layer.

For example, in a case where the dimension d1 of the first groove 51 in the first direction Y is in a range from 1.4 μm to 1.6 μm, and the dimension d2 of the second groove 52 in the first direction Y is in a range from 0.7 μm to 0.8 μm, thicknesses of the first filling layer 601 and the second filling layer 602 may be approximately equal. For example, in a case where the dimension d1 of the first groove 51 in the first direction Y is 1.4 μm, and the dimension d2 of the second groove 52 in the first direction Y is 0.7 μm, the thickness of the first filling layer 601 is 0.7 μm, and the thickness of the second filling layer 602 is 0.7 μm. Details will not be limited here.

For example, the first planarization layer 207 and the second planarization layer 209 are made of a light-transmitting organic insulating material, such as polyimide (PI).

Since the first groove 51 is filled with the first filling layer 601 that is arranged in the same layer as the first planarization layer 207 and the second filling layer 602 that is arranged in the same layer as the second planarization layer 209, the second groove 52 is filled with the second filling layer 602 that is arranged in the same layer as the second planarization layer 209, the requirement of filling an organic material in the groove 50 may be satisfied, and the filling layer 60 in the first groove 51 and the filling layer 60 in the second groove 52 may be synchronously formed in the steps of forming the first planarization layer 207 and the second planarization layer 209, which facilitates the manufacturing. The specific manufacturing steps will be described below, and details are not provided here.

In some embodiments, referring to FIG. 6 again, the opening peripheral region F further includes a first encapsulation dam region C and a second isolation region B. The first encapsulation dam region C is located between the first isolation region D and the display region AA, and surrounds the first isolation region D. The second isolation region B is located between the first encapsulation dam region C and the display region AA, and surrounds the first encapsulation dam region C. The first encapsulation dam region C is provided therein with at least one first encapsulation dam 70, the at least one first encapsulation dam 70 surrounds the opening region H, and the at least one first encapsulation dam 70 is disposed on the side of the at least one insulating layer 22 away from the substrate. The second isolation region B is further provided therein with a plurality of second isolation columns 80, each second isolation column 80 surrounds the opening region H, and the plurality of second isolation columns 80 are arranged at intervals in the radial direction of the opening region H.

In some examples, referring to FIGS. 5 and 6 again, the opening peripheral region F between the display region AA and the opening region H includes the second isolation region B, the first encapsulation dam region C and the first isolation region D, the second isolation region B, the first encapsulation dam region C and the first isolation region D each surround the opening region H, and the second isolation region B, the first encapsulation dam region C and the first isolation region D are sequentially arranged in a radial direction (i.e., the second direction X) gradually proximate to the opening region H. By providing the second isolation region B, the first encapsulation dam region C and the first isolation region D in the opening peripheral region F, the encapsulation ability of the opening peripheral region F is further improved.

As shown in FIG. 6, the first encapsulation dam region C is provided therein with one first encapsulation dam 70. In the above structure of the opening peripheral region H, a groove 50 is arranged between adjacent first isolation columns 40 in the first isolation region D, and an organic material is filled in the groove 50, so that the encapsulation ability of the opening peripheral region F of the display panel 100 is improved. Therefore, it may be possible to reduce the number of encapsulation dams 70, and in turn reduce the width of the opening peripheral region F, that is, reduce the size of the opening peripheral region F in the second direction X. As a result, the screen-to-body ratio of the display panel is improved.

It should be noted that the first encapsulation dam region C may be provided with a plurality of first encapsulation dams 70, and the plurality of first encapsulation dams 70 are arranged at intervals in the second direction X. The number of the first encapsulation dams 70 in the first encapsulation dam region C is not limited here.

Each of the plurality of second isolation columns 80 in the second isolation region B is disposed around the opening region H. By arranging the plurality of second isolation columns 80 and the plurality of first isolation columns 40, the encapsulation capability of the opening peripheral region F of the display panel 100 is improved.

In some embodiments, as shown in FIG. 6, a portion of the at least one insulating layer 22 located between two adjacent second isolation columns 80 is provided therein with a depression portion 90.

In some examples, as shown in FIG. 6, the depression portion 90 is arranged around the opening region H. The depression portion 90 between the two adjacent second isolation columns 80 has similar functions as the groove 50 between the two adjacent first isolation columns 40. Thus, the encapsulation ability of the opening peripheral region H of the display panel 100 is further improved.

In some examples, a material for forming the first planarization layer 207 may be filled in the depression portion 90. That is, a filling layer in the depression portion 90 is formed synchronously in the step of forming the first planarization layer 207. Alternatively, a material for forming the second planarization layer 209 may be filled in the depression portion 90. That is, the filling layer in the depression portion 90 is formed synchronously in the step of forming the second planarization layer 209.

In the display panel 100 described above, the groove 50 is arranged between the adjacent first isolation columns 40 in the first isolation region D; the organic material is filled in the groove 50; the opening peripheral region F includes the second isolation region B, the first encapsulation dam region C, and the first isolation region D; and the depression portion 90 is arranged between the adjacent second isolation columns 80 in the second isolation region B. Therefore, it is possible to effectively improve the encapsulation ability of the opening peripheral region F of the display panel 100, prevent the crack from extending to the display region AA, avoid the GDS, and improve the yield of the product.

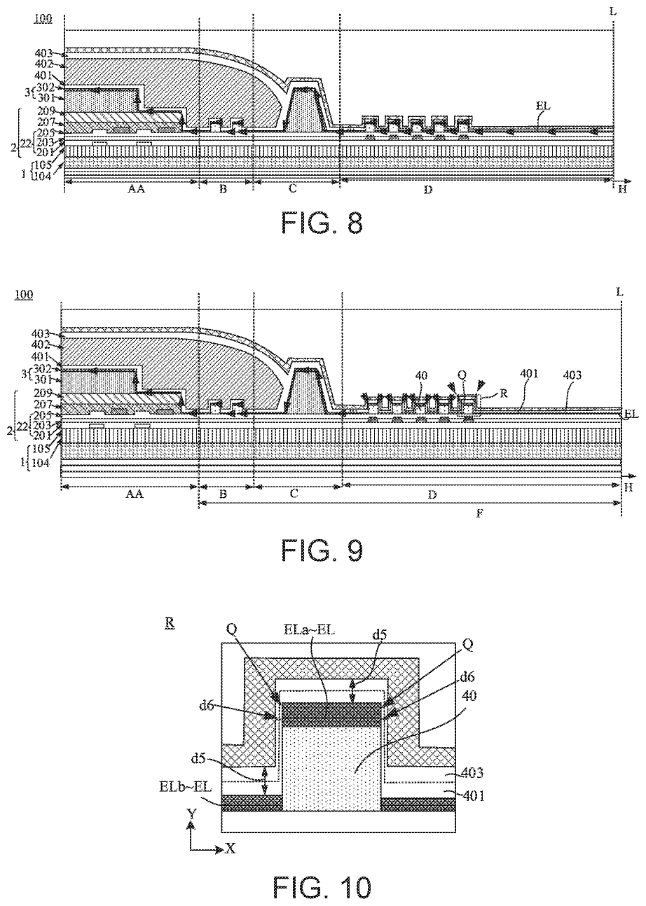

However, the inventors have also found that the EL film layer is provided at the position of the opening of the display region AA of the flexible panel, so that the water vapor intrudes into the EL material, which causes the GDS. There are mainly two paths of the water vapor intrusion causing encapsulation failure in the opening peripheral region. One path is that the water vapor intrudes along the opening cutting edge line L; as shown in FIG. 8, the arrows indicate that the water vapor intrudes into the display region AA from the opening cutting edge line L; and the water vapor enters the display region AA along the film layer of the EL material, resulting in the GDS.

The other path is that the water vapor intrudes along broken positions Q of the EL film layer on the first isolation column 40; as shown in FIGS. 9 and 10, the first isolation column 40 is protuberant with respect to film layers on two sides of the first isolation column 40 in the second direction X, which causes the EL film layer to be segmented; therefore, the EL film layer forms a portion ELa that is located on a side of the first isolation column 40 away from the substrate 1 and portions ELb that are located on the film layers on the two sides of the first isolation column 40 in the second direction X, and the portion ELa and the portions ELb are disconnected to each other. The water vapor intrudes into the EL film layer along the broken positions Q of the EL film layer on the first isolation column 40, and continues to intrude the display region AA from the EL film layer along the path indicated by the arrows in the figure, which results in the GDS, and in turn causes poor product. Therefore, the intrusion of water vapor from the EL film layer causes the GDS, which results in high requirement of the encapsulation ability of the opening peripheral region.

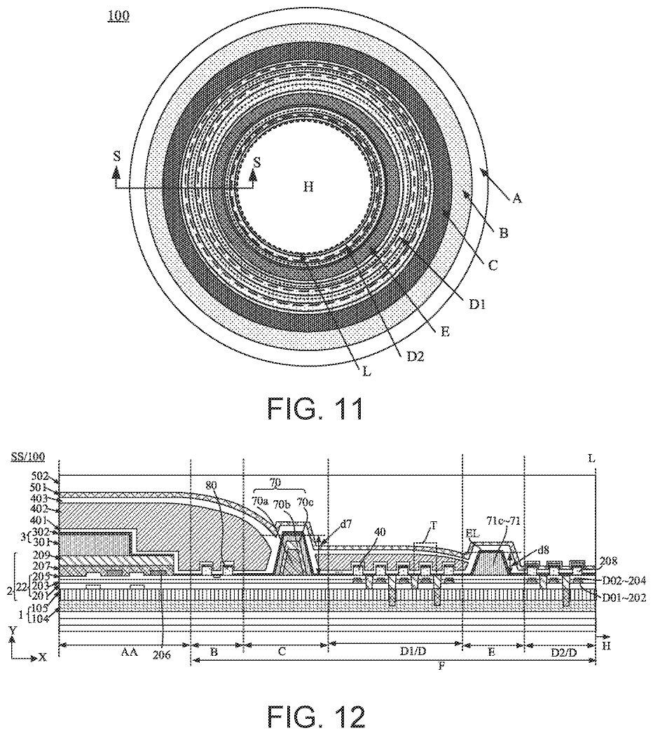

Based on this, in some embodiments, as shown in FIGS. 11 and 12, the opening peripheral region F includes two first isolation regions, which are a first isolation sub-region D1 and a second isolation sub-region D2. The first isolation sub-region D1 and the second isolation sub-region D2 are arranged at intervals in the radial direction of the opening region H, and the second isolation sub-region D2 is closer to the opening region H than the first isolation sub-region D1. The display panel 100 further includes a light-emitting device layer 3, a first inorganic encapsulation film layer 401, an organic encapsulation film layer 402 and a second inorganic encapsulation film layer 403.

The light-emitting device layer 3 is disposed on a side of the driving circuit layer 2 away from the substrate 1, and the light-emitting device layer 3 is located in the display region AA and the opening peripheral region F. The first inorganic encapsulation film layer 401 is disposed on a side of the light-emitting device layer 3 away from the substrate 1, and the first inorganic encapsulation film layer 401 is located in the display region AA and the opening peripheral region F. The organic encapsulation film layer 402 is disposed on a side of the first inorganic encapsulation film layer 401 away from the substrate 1, and the organic encapsulation film layer 402 is located in the display region AA, the second isolation region B, and the first isolation sub-region D1. The second inorganic encapsulation film layer 403 is disposed on a side of the organic encapsulation film layer 402 away from the substrate 1, and the second inorganic encapsulation film layer 403 is located in the display region AA and the opening peripheral region F.

For example, materials of the first inorganic encapsulation film layer 401 and the second inorganic encapsulation film layer 403 may each include silicon oxide, silicon nitride, silicon oxynitride, aluminum oxide, titanium oxide, zirconium oxide, tin oxide, and/or the like. A material of the organic encapsulation film layer 402 may include acrylic, polyimide (PI), polyamide (PA), benzocyclobutene (BCB) and/or the like. The first inorganic encapsulation film layer 401, the second inorganic encapsulation film layer 403 and the organic encapsulation film layer 402 may improve the encapsulation ability of the display panel 100.

In some examples, as shown in FIGS. 11 and 12, the first isolation sub-region D1 is close to the opening region H, and is arranged around the opening region H; in the radial direction of the opening region H, i.e., in the second direction X, the second isolation sub-region D2 is farther from the opening region H than the first isolation sub-region D1, and the first isolation sub-region D1 and the second isolation sub-region D2 are arranged at intervals; and a second encapsulation dam region E around the opening region H may be provided between the first isolation sub-region D1 and the second isolation sub-region D2. As for the introduction of the second encapsulation dam region E, reference may be made to the following content, and details will not be provided here.

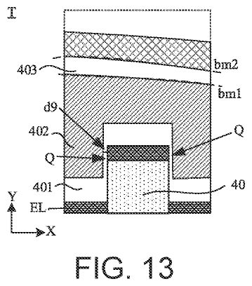

The EL film layer is located in the light-emitting device layer 3, and the EL film layer is located in the display region AA and the opening peripheral region F. The structure of the EL film layer at the first isolation column 40 is as described above, and details are not repeated here. By comparing FIGS. 10 and 13, the path of the water vapor intrusion, i.e., the intrusion of the water vapor along the broken positions Q of the EL film layer on the first isolation column 40, occurs in the following situation: in some embodiments, as shown in FIG. 10, there is the first isolation sub-region D1, and thicknesses of the first inorganic encapsulation film layer 401 and the second inorganic encapsulation film layer 403 on a sidewall of the first isolation column 40 are significantly reduced, resulting in a poor encapsulation ability of the first inorganic encapsulation film layer 401 and the second inorganic encapsulation film layer 403 at the broken positions Q of the EL film layer. For example, a size of both the first inorganic encapsulation film layer 401 and the second inorganic encapsulation film layer 403 in the first direction Y is d5. Since the first isolation column 40 is protuberant with respect to film layers on two sides thereof in the second direction X, a size d6 of both the first inorganic encapsulation film layer 401 and the second inorganic encapsulation film layer 403 in the second direction X at the broken position Q of the EL film layer is significantly small. Therefore, a thickness of film layers of the first inorganic encapsulation film layer 401 and the second inorganic encapsulation film layer 403 for protecting the broken position of the EL film layer is obviously insufficient, which causes the intrusion of water vapor.

Referring to FIG. 13 again, the organic encapsulation film layer 402 is located in the display region AA and the second isolation region B, and is further located in the first isolation sub-region D1. At the position of the first isolation column 40, the organic encapsulation film layer 402 is on the first inorganic encapsulation film layer 401 away from the substrate 1, and a surface bm1 of the organic encapsulation film layer 402 away from the substrate 1 is smooth, so that a surface bm2 of the second inorganic encapsulation film layer 403 formed at the position of the first isolation column 40 may be flat. Therefore, the film structure of the second inorganic encapsulation film layer 403 is effectively improved, the thickness of the second inorganic encapsulation film layer 403 is uniform, and the sidewall of the second inorganic encapsulation film layer 403 will not be obviously thinned on the position of the first isolation column 40. In addition, the organic encapsulation film layer 402 is further added at the position of the first isolation column 40 in the first isolation sub-region D1, so that the encapsulation ability of the display panel 100 is further improved, the problem of water vapor intruding from the broken position Q of the EL film layer is avoided, the encapsulation structure of the display panel is further optimized, and the encapsulation ability of the display panel is improved.

In some embodiments, referring to FIGS. 6 and 12 again, the driving circuit layer 2 further includes a first gate layer 202, a second gate layer 204, a first source-drain metal layer 206 and a second source-drain metal layer 208. The at least one insulating layer 22 includes a first insulating layer 201, a second insulating layer 203, and an interlayer dielectric layer 205. The first gate layer 202 is disposed on a side of the first insulating layer 201 away from the substrate 1. The second insulating layer 203 is disposed on a side of the first gate layer 202 away from the substrate 1. The second gate layer 204 is disposed on a side of the second insulating layer 203 away from the substrate 1. The interlayer dielectric layer 205 is disposed on a side of the second gate layer 202 away from the substrate 1. The first source-drain metal layer 206 is disposed on a side of the interlayer dielectric layer 205 away from the substrate 1. The first planarization layer 207 is disposed on a side of the first source-drain metal layer 206 away from the substrate 1. The second source-drain metal layer 208 is disposed on a side of the first planarization layer 207 away from the substrate 1. The second planarization layer 209 is disposed on a side of the second source-drain metal layer 208 away from the substrate 1. The display panel 100 further includes second isolation columns 80, and the first isolation columns 40 and the second isolation columns 80 are arranged in the same layer as the second source-drain metal layer 208.

For example, a material of the first gate layer 202 may include a copper-based metal, an aluminum-based metal, or a nickel-based metal. For example, the copper-based metal is a copper-based metal alloy with stable property, such as copper (Cu), copper-zinc alloy (CuZn), copper-nickel alloy (CuNi) or copper-zinc-nickel alloy (CuZnNi). A material of the second gate layer 204 may be one or more of molybdenum, copper, aluminum, and titanium, or one or more alloys of any combinations of molybdenum, copper, aluminum, and titanium, or other suitable materials.

For example, materials of the first insulating layer 201, the second insulating layer 203, and the interlayer dielectric layer 205 may each include silicon nitride (SiNₓ), silicon oxide (SiOₓ), silicon oxynitride (SiNₓO_{y}), or other suitable materials. The first insulating layer 201 may isolate the first gate layer 202 from a semiconductor layer (not shown in the figures) located on a side of the first insulating layer 201 proximate to the substrate 1. The second insulating layer 203 may isolate the first gate layer 202 from the second gate layer 204. The interlayer dielectric layer 205 may isolate the second gate layer 204 from the first source-drain metal layer 206.

For example, materials of the first source-drain metal layer 206 and the second source-drain metal layer 208 may each include a metal, for example, may be one or more of molybdenum, copper, aluminum, and titanium, or one or more alloys of any combinations of molybdenum, copper, aluminum, and titanium, or other suitable materials.

The first isolation columns 40 and the second isolation columns 80 are arranged in the same layer as the second source-drain metal layer 208, which means that during the process of forming the second source-drain metal layer 208 of the driving circuit layer 2 in the display region AA, the first isolation columns 40 and the second isolation columns 80 are synchronously formed. In this way, the manufacturing steps are saved, which facilitates the forming of the first isolation columns 40 and the second isolation columns 80. As for the specific process, reference is made to the following manufacturing method, and details are not provided here.

In some embodiments, referring to FIG. 12 again, a region between the first isolation sub-region D1 and the second isolation sub-region D2 is a second encapsulation dam region E; the second encapsulation dam region E is provided therein with at least one second encapsulation dam 71; the at least one second encapsulation dam 71 surrounds the opening region H; and the at least one second encapsulation dam 71 is disposed on a side of the driving circuit layer 2 away from the substrate 1.

In some examples, as shown in FIG. 12, the second encapsulation dam region E is disposed around the opening region H, the second encapsulation dam region E is provided therein with one second encapsulation dam 71, and the second encapsulation dam 71 is disposed around the opening region H. The second encapsulation dam 71 may improve the encapsulation ability of the opening peripheral region F of the display panel 100.

It should be noted that there may be a plurality of second encapsulation dams 71, and the plurality of second encapsulation dams 71 are arranged in the second direction X. The number of the second encapsulation dams 71 in the second encapsulation dam region E is not limited here.

In some embodiments, referring to FIG. 12 again, a thickness d7 of the first encapsulation dam 70 in the first direction Y is greater than a thickness d8 of the second encapsulation dam 71 in the first direction Y.

In some examples, as shown in FIG. 12, one first encapsulation dam 70 is disposed in the first encapsulation dam region C, one second encapsulation dam 71 is disposed in the second encapsulation dam region E, the thickness d7 of the first encapsulation dam 70 in the first direction Y is greater than the thickness d8 of the second encapsulation dam 71 in the first direction Y. Therefore, a material for forming the encapsulation dam may be saved to a maximum extent in a case where the encapsulation requirements are met.

In some embodiments, referring again to FIG. 12, the light-emitting device layer 3 includes a pixel defining layer 301, an anode layer, a light-emitting layer, and a cathode layer 302. The pixel defining layer 301 is used to define positions of the light-emitting devices in the display region. The pixel defining layer 301 includes a plurality of holes, the anode layer includes a plurality of anodes, and the light-emitting layer includes a plurality of light-emitting portions. Each hole is provided therein with an anode and a light-emitting portion. The cathode layer 302 is located on an uppermost layer of the light-emitting device layer 3. That is, the cathode layer 302 covers the light-emitting portion in each hole, the pixel defining layer 301, a surface of the driving circuit layer away from the substrate (for example, portions of the second planarization layer 209 not covered by the pixel defining layer), a plurality of isolation columns, and a plurality of encapsulation dams. That is, the cathode layer 302 completely covers at least an entire region including the display region and the opening peripheral region.

It should be noted that, referring to FIGS. 6, 7A and 12 again, the light-emitting layer and the cathode layer 302 of the light-emitting device layer 3 belong to the above EL film layer.

As shown in FIG. 12, the first encapsulation dam 70 includes a first portion 70a, a second portion 70b and a third portion 70c. The first portion 70a is arranged in the same layer as the first planarization layer 207. The second portion 70b is disposed on a side of the first portion 70a away from the substrate 1, and the second portion 70b is arranged in the same layer as the second planarization layer 209. The third portion 70c is disposed on a side of the second portion 70b away from the substrate 1, and the third portion 70c is arranged in the same layer as the pixel defining layer 301. The second encapsulation dam 71 includes a third portion 71c arranged in the same layer as the pixel defining layer 301.

That is, during the step of forming the first planarization layer 207 of the driving circuit layer 2, the first portion 70a of the first encapsulation dam 70 is synchronously formed. During the step of forming the second planarization layer 209 of the driving circuit layer 2, the second portion 70b of the first encapsulation dam 70 is synchronously formed. During the step of forming the pixel defining layer 301 of the light-emitting device layer 3, the third portion 70c of the first encapsulation dam 70 and the third portion 71c of the second encapsulation dam 71 are synchronously formed.

For example, a material of the pixel defining layer 301 may include polyimide.

In some embodiments, referring to FIGS. 6, 7A and 12 again, the first isolation region D is further provided with therein a plurality of first patterns D01 and a plurality of second patterns D02. The plurality of first patterns D01 are located in the first gate layer 202, and the plurality of second patterns D02 are located in the second gate layer 204. Each first pattern D01 and each second pattern D02 surrounds the opening region H. Orthographic projections of a first isolation column 40, a first pattern D01, and a second pattern D02 on the substrate 1 have a common overlapping region.

For example, the number of the plurality of first patterns D01 and the number of the plurality of second patterns D02 are each equal to the number of the plurality of first isolation columns 40; a second pattern D02 is disposed below each first isolation column 40; and a first pattern D01 is disposed below each second pattern D02.

Due to the plurality of first patterns D01 and the plurality of second patterns D02, the first isolation columns 40 may be elevated, and the crack in the substrate 1 may be alleviated.

In some embodiments, referring to FIG. 12 again, the display panel 100 further includes an inorganic insulating layer 501 and an organic cover layer 502. The inorganic insulating layer 501 is disposed on a side of the second inorganic encapsulation film layer 403 away from the substrate 1, and the inorganic insulating layer 501 is located in the display region AA and the opening peripheral region F. The organic cover layer 502 is disposed on a side of the inorganic insulating layer 501 away from the substrate 1, and is located in the display region AA and the opening peripheral region F.

For example, a material of the inorganic insulating layer 501 includes an inorganic material such as silicon nitride. The inorganic insulating layer 501 may be formed by, for example, a deposition process, and the inorganic insulating layer 501 is a thin layer with a relatively uniform thickness covering the side of the second inorganic encapsulation layer 403 away from the substrate. A material of the organic cover layer 502 includes an organic polymer material. For example, a surface of the organic cover layer 502 is flat, and the organic cover layer 502 can fill up depression(s). Both the inorganic insulating layer 501 and the organic cover layer 502 protect other film layers in the display panel.

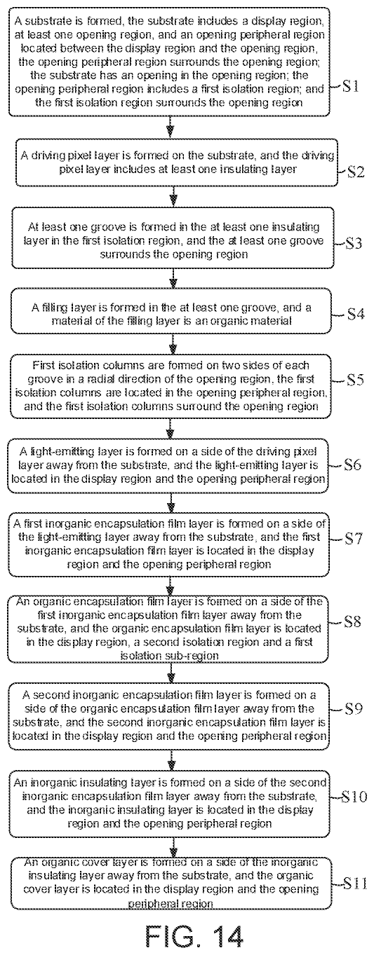

A second aspect of the present disclosure provides a method for manufacturing a display panel, as shown in FIG. 14, the method includes S1 to S5.

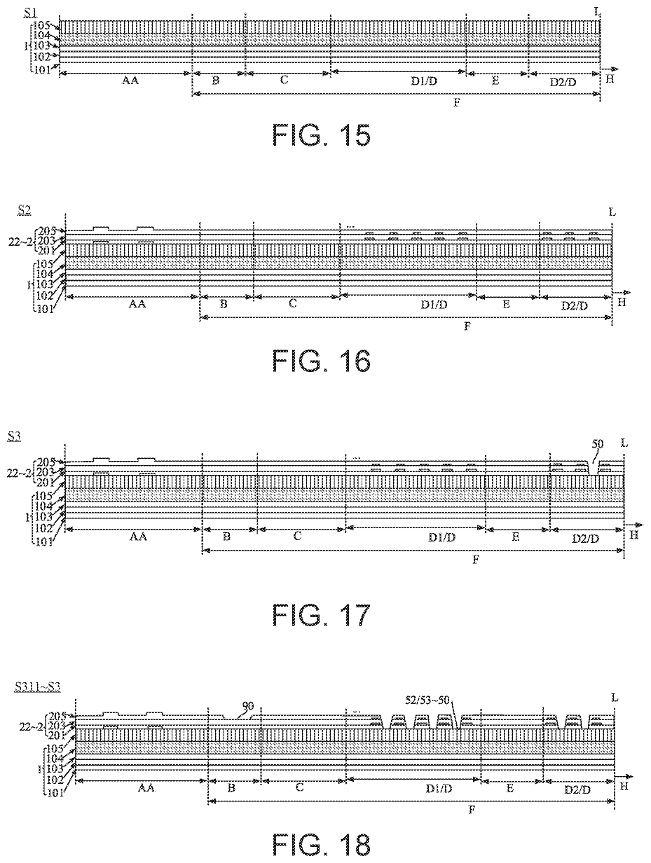

In S1, a substrate 1 is formed. As shown in FIG. 15, the substrate 1 has a display region AA, at least one opening region H, and an opening peripheral region F located between the opening region H and the display region AA, and the opening peripheral region F surrounds the opening region H. The substrate 1 has an opening in the opening region H. The opening peripheral region F includes a first isolation region D, and the first isolation region D surrounds the opening region H.

The substrate 1 may be a single-layer structure or a multi-layer structure. As shown in FIG. 15, the substrate 1 may include a first flexible base layer 101, a first barrier layer 102, a second flexible base layer 103, a second barrier layer 104, and a buffer layer 105 that are stacked in sequence.

The description that the substrate 1 has an opening in the opening region H means that an opening penetrating through the substrate 1 is formed in the opening region H.

In some examples, considering an example in which the display panel 100 shown in FIG. 12 is formed, the first isolation region D includes a first isolation sub-region D1 and a second isolation sub-region D2 that are spaced apart, and the opening peripheral region F further includes a second isolation region B, a first encapsulation dam region C, and a second encapsulation dam region E. The display region AA, the second isolation region B, the first encapsulation dam region C, the first isolation sub-region D1, the second encapsulation dam region E, the second isolation sub-region D2, the opening region H of the substrate 1 are consistent with a display region AA, a second isolation region B, a first encapsulation dam region C, a first isolation sub-region D1, a second encapsulation dam region E, a second isolation sub-region D2, and an opening region H of the display panel 100 to be formed, respectively.

It should be noted that, considering an example in which the display panel 100 shown in FIG. 6 is formed, the opening peripheral region F includes a second isolation region B and a first encapsulation dam region C. The display region AA, the second isolation region B, the first encapsulation dam region C, the first isolation region D, and the opening region H of the substrate 1 are consistent with a display region AA, a second isolation region B, a first encapsulation dam region C, a first isolation region D, and an opening region H of the display panel 100 to be formed, respectively. The substrate 1 may be formed according to the foregoing content, and details are not repeated here.

In the present disclosure, the method of manufacturing the display panel is described by taking the display panel 100 shown in FIG. 12 as an example.

In S2, as shown in FIG. 16, a driving circuit layer 2 is formed on the substrate 1; the driving circuit layer 2 includes at least one insulating layer 22; and the at least one insulating layer 22 is located in the display region AA and the opening peripheral region F.

The at least one insulating layer 22 is located in the display region AA, the second isolation region B, the first encapsulation dam region C, the first isolation sub-region D1, the second encapsulation dam region E, and the second isolation sub-region D2.

In some examples, referring to FIG. 16 again, the at least one insulating layer 22 includes a first insulating layer 201, a second insulating layer 203, and an interlayer dielectric layer 205.

In some examples, as shown in FIG. 12, the driving circuit layer 2 further includes a first gate layer 202, a second gate layer 204, a first source-drain metal layer 206 and a second source-drain metal layer 208. The at least one insulating layer 22 includes a first insulating layer 201, a second insulating layer 203, and an interlayer dielectric layer 205. The first gate layer 202 is disposed on a side of the first insulating layer 201 away from the substrate 1. The second insulating layer 203 is disposed on a side of the first gate layer 202 away from the substrate 1. The second gate layer 204 is disposed on a side of the second insulating layer 203 away from the substrate 1. The interlayer dielectric layer 205 is disposed on a side of the second gate layer 202 away from the substrate 1. The first source-drain metal layer 206 is disposed on a side of the interlayer dielectric layer 205 away from the substrate 1. The first planarization layer 207 is disposed on a side of the first source-drain metal layer 206 away from the substrate 1. The second source-drain metal layer 208 is disposed on a side of the first planarization layer 207 away from the substrate 1. The second planarization layer 209 is disposed on a side of the second source-drain metal layer 208 away from the substrate 1. The display panel 100 further includes second isolation columns 80, and first isolation columns 40 and the second isolation columns 80 are arranged in the same layer as the second source-drain metal layer 208. The specific content is as described above, which will not be repeated here.

For example, the first gate layer 202, the second gate layer 204, the first source-drain metal layer 206 and the second source-drain metal layer 208 are formed by a patterning process. The first insulating layer 201, the second insulating layer 203, and the interlayer dielectric layer 205 are formed by a coating process.

In S3, as shown in FIGS. 17 to 19, at least one groove 50 is formed in the at least one insulating layer 22 in the first isolation region D, and the at least one groove 50 surrounds the opening region.

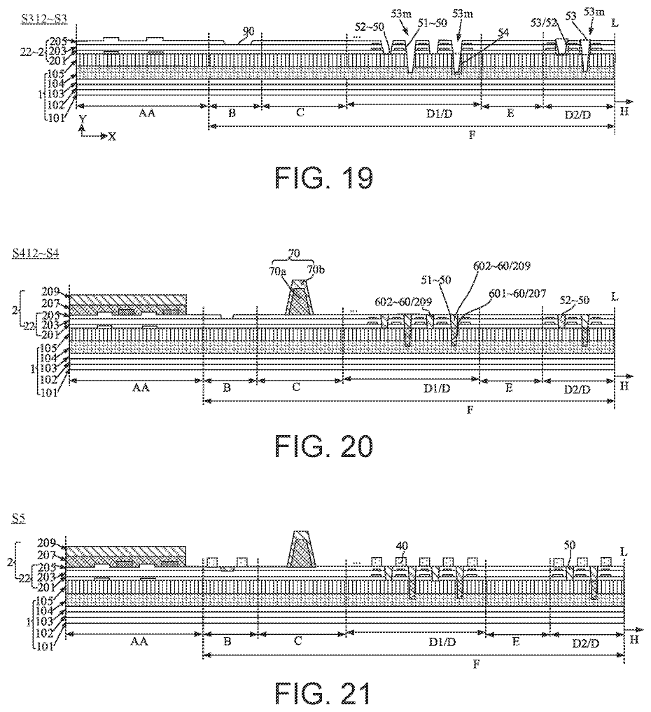

In some examples, as shown in FIG. 17, one groove 50 may be formed in the at least one insulating layer 22 in the first isolation region D. In some examples, as shown in FIG. 18, a plurality of grooves 50 with the same depth may be formed in the at least one insulating layer 22 in the first isolation region D. In some examples, as shown in FIG. 19, a plurality of grooves 50 with different depths may be formed in the at least one insulating layer 22 in the first isolation region D, and the grooves 50 with different depths are alternately arranged. It should be noted that the depth type and the number of the grooves 50 are not limited in the present disclosure.

For example, one groove 50 is formed by one patterning process, or the plurality of grooves 50 with the same depth are formed by one patterning process. Alternatively, the plurality of grooves 50 with different depths are formed by two patterning processes. As for details, reference can be made to the following content, which will not be provided here.

In S4, as shown in FIG. 20, a filling layer 60 is formed in the at least one groove 50, and a material of the filling layer 60 is an organic material.

In some examples, considering an example in which the display panel 100 as shown in FIG. 12 is formed, as shown in FIG. 20, a plurality of grooves 50 with different depths may be formed in the at least one insulating layer 22 in the first isolation region D, and the grooves 50 with different depths are alternately arranged. The grooves 50 is each filled with an organic material.

For example, the organic material may include polyimide (PI), polyamide (PA), or the like.

In some examples, as shown in FIG. 20, the grooves 50 with different depths may be the first grooves 51 and the second grooves 52 as described above. A filling layer 60 in the first groove 51 includes a first filling layer 601 and a second filling layer 602, and a filling layer 60 in the second groove 52 includes a second filling layer 602. The first filling layer 601 may be arranged in the same layer as the first planarization layer 207, and the second filling layers 602 may be arranged in the same layer as the second planarization layer 209.

Since a first portion 70a included in the first encapsulation dam 70 in the first encapsulation region C may be arranged in the same layer as the first planarization layer 207, a second portion 70b included in the first encapsulation dam 70 in the first encapsulation region C may be arranged in the same layer as the second planarization layer 209. Therefore, when the filling layer 60 is formed, the first portion 70a and the second portion 70b of the first encapsulation dam 70 may be formed at the same time.

In S5, as shown in FIG. 21, first isolation columns 40 are formed on two sides of each groove 50 in a radial direction of the opening region H (a second direction X), the first isolation columns 40 are located in the first isolation region D, and the first isolation columns 40 surround the opening region H.

In some examples, the first isolation columns 40 are formed by a patterning process. As shown in FIG. 21, first isolation columns 40 are formed on two sides of each groove 50 of the plurality of grooves 50 in the radial direction of the opening region H (the second direction X).

In some examples, referring to FIG. 21 again, the first isolation columns 40 and the second isolation columns 80 in the second isolation region B are arranged in the same layer as a second source-drain metal layer 208 of the display panel 100. The second source-drain metal layer 208 is formed by a patterning process, and the second isolation columns 80 and the first isolation columns 40 are simultaneously formed in the same step.

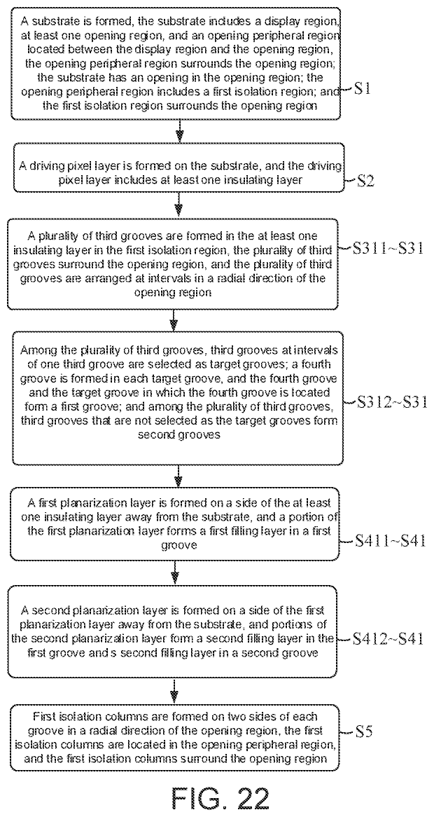

In some embodiments, as shown in FIG. 22, the step S3 of forming the at least one groove 50 on the at least one insulating layer 22 in the first isolation region D includes S31.

In S31, as shown in FIG. 19, a plurality of grooves 50 are formed in the at least one insulating layer 22 in the first isolation region D, and the plurality of grooves 50 include first grooves 51 and second grooves 52 that are arranged alternately in the radial direction of the opening region H.

For example, a dimension of the first groove 51 in the first direction Y is in a range from 1.4 μm to 1.6 μm. A dimension of the second groove 52 in the first direction Y is in a range from 0.7 μm to 0.8 μm. As for details, reference can be made to the above description, which will not be repeated here.

As shown in FIG. 22, the step S31 of forming the plurality of grooves on the at least one insulating layer 22 in the first isolation region D includes S311 to S312.

In S311, as shown in FIG. 18, a plurality of third grooves 53 are formed in the at least one insulating layer 22 in the first isolation region D, the plurality of third grooves 53 surround the opening region H, and the plurality of third grooves 53 are arranged at intervals in the radial direction of the opening region H (i.e., the second direction X).

For example, positions of third grooves 53 to be formed are irradiated by using a mask Mask, and then the at least one insulating layer 22 subjected to a light treatment is etched through a dry etching process, so as to form the plurality of third grooves 53 arranged at intervals in the radial direction of the opening region H (that is, the second direction X).

It will be understood that, referring to FIG. 18 again, a depression portion 90 may be formed in the second isolation region B by the same photolithography process.

In S312, as shown in FIG. 19, among the plurality of third grooves 53, every other third groove 53 is selected as a target groove 53m; and a fourth groove 54 is formed in each target groove 53m. The fourth groove 54 and the target groove 53m in which the fourth groove 54 is located form a first groove 51. Third grooves 53 among the plurality of third grooves 53 that are not selected as target grooves 53m form second grooves 52.

For example, positions of the target grooves 53m are irradiated by using a mask Mask, and then the target grooves 53m are etched through a dry etching process, so as to form the first grooves 51. Thus, the plurality of first grooves 51 and the plurality of second grooves 52 are formed and arranged at intervals in the radial direction of the opening region H (i.e., the second direction X).

It will be understood that the fourth grooves 54 are closer to the substrate 1 than the third grooves 53.

It should be noted that, a third groove 53 closest to the opening region H in the first isolation sub-region D1 may be selected as a target groove 53m, or a second third groove 53 closest to the opening region H may be selected as a target groove 53m, which is not limited here. A method for selecting target grooves 53m in the second isolation sub-region D2 is the same as the above description, and details are not repeated here.

As shown in FIG. 22, the step S4 of forming the filling layer 60 in the at least one groove 50 includes S41.

In S41, the first filling layer 601 and the second filling layer 602 are formed in the first groove 51, and the second filling layer 602 is formed in the second groove 52, which includes S411 to S412.

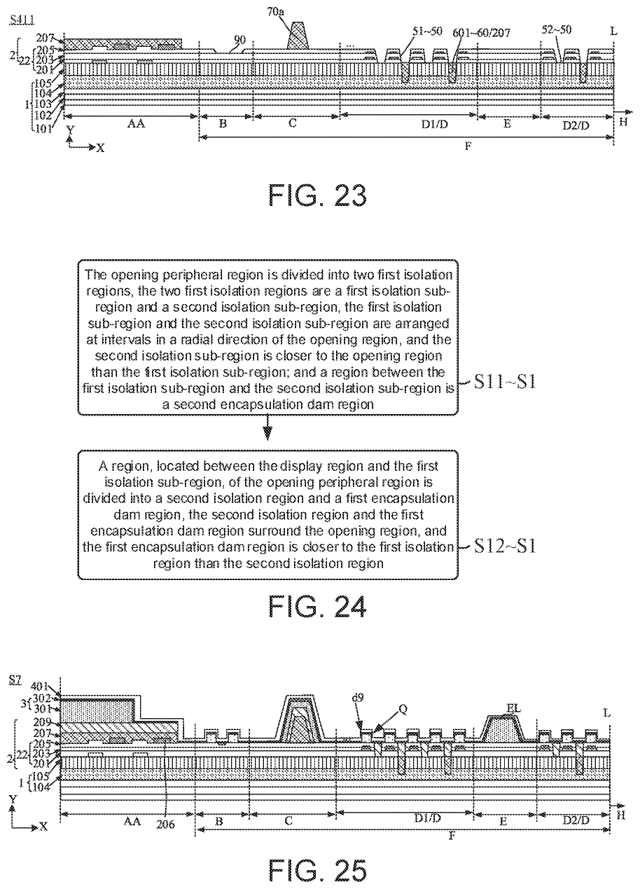

In S411, as shown in FIG. 23, a first planarization layer 207 is formed on the side of the at least one insulating layer 22 away from the substrate 1, and a portion of the first planarization layer 207 form the first filling layer 601 of the first groove 51.

The first planarization layer 207 is formed by using a coating process. The portion of the first planarization layer 207, i.e., a portion of the first planarization layer 207 whose orthographic projection on the substrate 1 coincides with an orthographic projection of the first groove 51 on the substrate 1, fills into the first groove 51 in this process step, so as to form the first filling layer 601 in the first groove 51.

Meanwhile, the first portions 70a of the first encapsulation dams 70 are formed in the first encapsulation region C, and the first portions 70a of the first encapsulation dams 70 are arranged in the same layer as the first planarization layer 207.

In S412, referring to FIG. 20 again, a second planarization layer 209 is formed on a side of the first planarization layer 207 away from the substrate 1, and portions of the second planarization layer 209 form the second filling layer 602 in the first groove 51 and the second filling layer 602 in the second groove 52.

The second planarization layer 209 is formed by using a deposition process. The portions of the second planarization layer 209, i.e., portions of the second planarization layer 209 whose orthographic projections on the substrate 1 coincide with orthographic projections of the first groove 51 and the second groove 52 on the substrate 1, fill into the first groove 51 and the second groove 52 in this process step, so as to form the second filling layer 602 in the first groove 51 and the second filling layer 602 in the second groove 52.

At the same time, the second portion 70b of the first encapsulation dam 70 is formed in the first encapsulation region C.

In some embodiments, as shown in FIG. 24, the step S1 of forming the substrate 1 further includes S11 to S12.

In S11, as shown in FIG. 15, the opening peripheral region F is divided into two first isolation regions D, the two first isolation regions D are a first isolation sub-region D1 and a second isolation sub-region D2, the first isolation sub-region D1 and the second isolation sub-region D2 are arranged at intervals in the radial direction of the opening region F, and the second isolation sub-region D2 is closer to the opening region H than the first isolation sub-region D1. A region between the first isolation sub-region D1 and the second isolation sub-region D2 is a second encapsulation dam region E.

In S12, as shown in FIG. 15, an region, located between the display region AA and the first isolation sub-region D1, of the opening peripheral region F is divided into a second isolation region B and a first encapsulation dam region C; the second isolation region B and the first encapsulation dam region C surround the opening region H; and the first encapsulation dam region C is closer to the first isolation region D1 than the second isolation region B.

The display region AA, the second isolation region B, the first encapsulation dam region C, the first isolation sub-region D1, the second encapsulation dam region E, the second isolation sub-region D2, and the opening region H of the substrate 1 are consistent with a display region AA, a second isolation region B, a first encapsulation dam region C, a first isolation sub-region D1, a second encapsulation dam region E, a second isolation sub-region D2, and an opening region H of the display panel 100 to be formed, respectively. Details are described as the forgoing description, which will not be repeated here.

As shown in FIG. 14, the method for manufacturing the display panel further includes the followings.

In S6, as shown in FIG. 6, a light-emitting device layer 3 is formed on a side of the driving circuit layer 2 away from the substrate 1, and the light-emitting device layer 3 is located in the display region AA and the opening peripheral region F.

The light-emitting device layer 3 includes a pixel defining layer 301, an anode layer, a light-emitting layer, and a cathode layer 302, and the specific structure of each film layer is described as the foregoing description.

For example, the pixel defining layer 301 is formed by a coating process, and then patterns of the pixel defining layer 301 are formed by a photolithography process. A third portion 70c of the first encapsulation dam 70 and a third portion 71c of the second encapsulation dam 71 are formed during the step of forming the pixel defining layer 301, and the third portion 70c of the first encapsulation dam 70 and the third portion 71c of the second encapsulation dam 71 belong to the patterns of the pixel defining layer 301.

In S7, as shown in FIG. 25, a first inorganic encapsulation film layer 401 is formed on a side of the light-emitting device layer 3 away from the substrate 1, and the first inorganic encapsulation film layer 401 is located in the display region AA and the opening peripheral region F.

For example, the first inorganic encapsulation film layer 401 is formed by a deposition process.

A thickness of the first inorganic encapsulation film layer 401 at the position of the first isolation column 40 is obviously small, and in particular, the thickness d9 of the first inorganic encapsulation film layer 401 in the second direction X at the broken position Q of the EL film layer is small, which may be seen in FIG. 13, and details will not be repeated here.

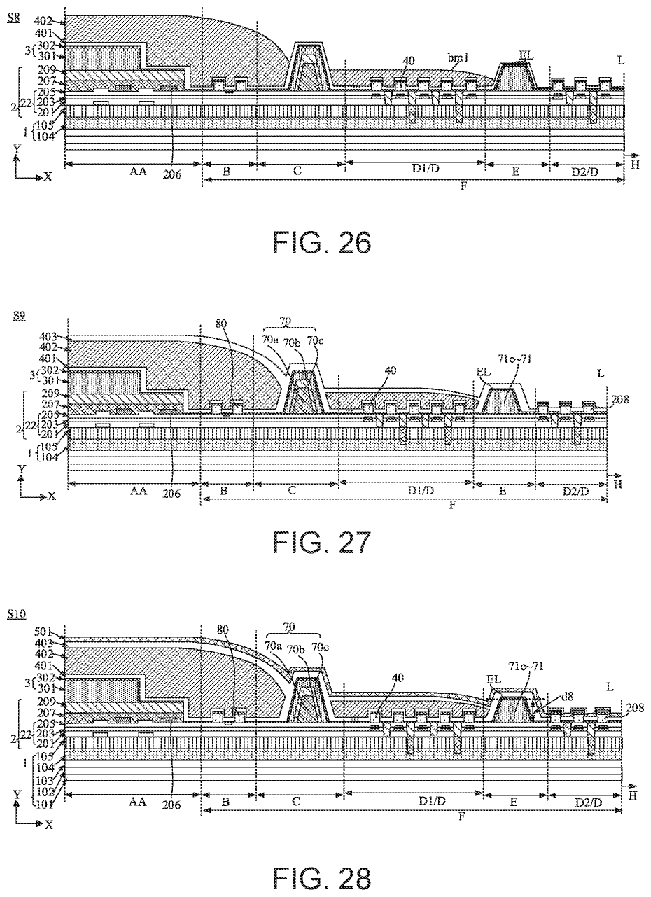

In S8, as shown in FIG. 26, an organic encapsulation film layer 402 is formed on a side of the first inorganic encapsulation film layer 401 away from the substrate 1, and the organic encapsulation film layer 402 is located in the display region AA, the second isolation region B and the first isolation sub-region D1.

For example, the organic encapsulation film layer 402 is formed by a coating process, and the organic encapsulation film layer 402 completely covers the first isolation sub-region D1, so as to cover the broken positions Q of the EL film layer vulnerable to water vapor intrusion. In addition, a surface of the organic encapsulation film layer 402 away from the substrate 1 is a smooth surface bm1.

In S9, as shown in FIG. 27, a second inorganic encapsulation film layer 403 is formed on a side of the organic encapsulation film layer 402 away from the substrate 1, and the second inorganic encapsulation film layer 403 is located in the display region AA and the opening peripheral region F.

For example, the second inorganic encapsulation film layer 403 is formed by a deposition process.

Since the organic encapsulation film layer 402 exists in the first isolation sub-region D1, and the surface of the organic encapsulation film layer 402 away from the substrate 1 is the smooth surface bm1, the second inorganic encapsulation film layer 403 formed on the side of the organic encapsulation film layer 402 away from the substrate 1 is flat. Thus, the film quality is good, and the water blocking capability is strong. It overcomes a problem that a film layer of the first inorganic encapsulation film layer 401 formed at the position of the first isolation column 40 is thin, which cannot protect the broken positions Q of the EL film layer. The flat first inorganic encapsulation film layer 401, the organic encapsulation film layer 402 and the second inorganic encapsulation film layer 403 form an effective protective film layer covering the broken positions Q of the EL film layer 302, which prevents the occurrence of the water vapor intruding from the broken positions Q of the EL film layer 302, and improves the yield of the display panel 100.

In S10, as shown in FIG. 28, an inorganic insulating layer 501 is formed on a side of the second inorganic encapsulation film layer 403 away from the substrate 1, and the inorganic insulating layer 501 is located in the display region AA and the opening peripheral region F.

For example, the inorganic insulating layer 501 is formed by a deposition process, and the encapsulation ability of the display panel 100 is further improved.

In S11, as shown in FIG. 12, an organic cover layer 502 is formed on a side of the inorganic insulating layer 501 away from the substrate 1, and the organic cover layer 502 is located in the display region AA and the opening peripheral region F.

For example, the organic cover layer 502 is formed by a coating process, and the encapsulation ability of the display panel 100 is further improved.

Beneficial effects of the method for manufacturing the display panel are the same as beneficial effects of the display panel provided in the first aspect of the present disclosure, and details are not repeated here.

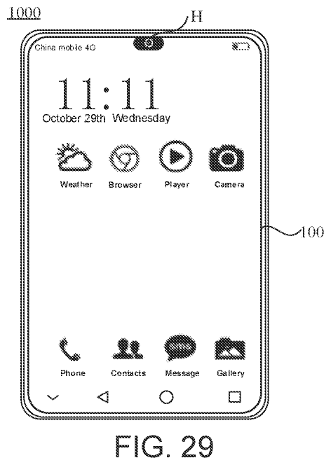

A third aspect of the present disclosure provides a display device 1000, as shown in FIG. 29, the display device 1000 includes the above display panel 100. The display device 1000 may be a mobile phone.

The display device provided in the embodiments of the present disclosure may be any device that displays images whether in motion (e.g., a video) or stationary (e.g., a static image), and whether literal or graphical. More specifically, it is contemplated that the described embodiments may be implemented in or associated with various electronic devices. The various electronic devices include (but are not limited to), for example, mobile phones, wireless devices, personal digital assistants (PDAs), hand-held or portable computers, GPS receivers/navigators, cameras, MP4 video players, video cameras, game consoles, watches, clocks, calculators, television monitors, flat panel displays, computer monitors, car displays (e.g., odometer displays), navigators, cockpit controllers and/or displays, camera view displays (e.g., rear view camera displays in vehicles), electronic photos, electronic billboards or signages, projectors, architectural structures, packaging and aesthetic structures (e.g., displays for images of a piece of jewelry).

In some examples, the display device may also be an electroluminescent display device or a photoluminescent display device. In a case where the display device is an electroluminescent display device, the electroluminescent display device may be an organic light-emitting diode (OLED) display device or a quantum dot light-emitting diode (QLED) display device. In a case where the display device is a photoluminescence display device, the photoluminescence display device may be a quantum dot photoluminescence display device.

Beneficial effects of the above display device are the same as beneficial effects of the display panel provided in the first aspect of the present disclosure, and details are not repeated here.

The foregoing descriptions are merely specific implementations of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, having a display region, at least one opening region, and an opening peripheral region located between the opening region and the display region, wherein the opening peripheral region surrounds the opening region, and the opening peripheral region includes a first isolation region surrounding the opening region;
the display panel comprising:
a substrate having an opening in the opening region;
a driving circuit layer disposed on a side of the substrate, wherein the driving circuit layer includes at least one insulating layer, and the at least one insulating layer is located in the display region and the opening peripheral region; and
a plurality of first isolation columns disposed on a side of the at least one insulating layer away from the substrate, wherein the plurality of first isolation columns are located in the first isolation region, each first isolation column surrounds the opening region, and the plurality of first isolation columns are arranged at intervals in a radial direction of the opening region;
wherein a portion of the at least one insulating layer located between at least two adjacent first isolation columns is provided therein with a groove, and the groove surrounds the opening region; and the groove is filled with a filling layer, and the filling layer is made of an organic material.

2. The display panel according to claim 1, wherein
a portion of the at least one insulating layer between every two adjacent first isolation columns is provided therein with a groove, grooves provided in the at least one insulating layer include first grooves and second grooves, a dimension of a first groove of the first grooves in a first direction is greater than a dimension of a second groove of the second grooves in the first direction, and the first direction is perpendicular to the substrate.

3. The display panel according to claim 2, wherein the first grooves and the second grooves are alternately arranged in the radial direction of the opening region; and/or
the dimension of the first groove in the first direction is in a range from 1.4 μm to 1.6 μm; and the dimension of the second groove in the first direction is in a range from 0.7 μm to 0.8 μm.

4. (canceled)

5. The display panel according to claim 2, wherein the substrate includes a barrier layer and a buffer layer that are stacked;
the at least one insulating layer includes a first insulating layer, a second insulating layer, and an interlayer dielectric layer; the first insulating layer is disposed on a side of the buffer layer away from the barrier layer, the second insulating layer is disposed on a side of the first insulating layer away from the barrier layer, and the interlayer dielectric layer is disposed on a side of the second insulating layer away from the barrier layer;
the first grooves reach the barrier layer, and the first grooves penetrate into the barrier layer; and
the second grooves reach the buffer layer.

6. The display panel according to claim 5, wherein a thickness of a portion, penetrated by the first groove, of the barrier layer in the first direction is a half of a thickness of the barrier layer in the first direction.

7. The display panel according to claim 1, wherein a dimension of an opening of the groove in a second direction is ⅓ to ⅔ of a distance, in the second direction, between two adjacent first isolation columns with the groove therebetween;
wherein the second direction is the radial direction of the opening region.

8. The display panel according to claim 2, wherein the driving circuit layer further includes a first planarization layer and a second planarization layer; the first planarization layer is disposed on the side of the at least one insulating layer away from the substrate, and the second planarization layer is disposed on a side of the first planarization layer away from the substrate;
a filling layer in the first groove includes a first filling layer and a second filling layer, and a filling layer in the second groove includes a second filling layer; and the first filling layer and the first planarization layer are arranged in a same layer, and the second filling layer in the first groove, the second filling layer in the second groove, and the second planarization layer are arranged in a same layer.

9. The display panel according to claim 1, wherein the opening peripheral region further includes a first encapsulation dam region and a second isolation region; the first encapsulation dam region is located between the first isolation region and the display region, and surrounds the first isolation region; the second isolation region is located between the first encapsulation dam region and the display region, and surrounds the first encapsulation dam region;
the first encapsulation dam region is provided therein with at least one first encapsulation dam, the at least one first encapsulation dam surrounds the opening region, and the at least one first encapsulation dam is disposed on the side of the at least one insulating layer away from the substrate; and
the second isolation region is provided therein with a plurality of second isolation columns, each second isolation column surrounds the opening region, and the plurality of second isolation columns are arranged at intervals in the radial direction of the opening region.

10. The display panel according to claim 9, wherein a portion of the at least one insulating layer between two adjacent second isolation columns is provided therein with a depression portion.

11. The display panel according to claim 1, wherein the opening peripheral region includes two first isolation regions, the two first isolation regions are respectively a first isolation sub-region and a second isolation sub-region, the first isolation sub-region and the second isolation sub-region are arranged at intervals in the radial direction of the opening region, and the second isolation sub-region is closer to the opening region than the first isolation sub-region;
the display panel further comprises:
a light-emitting device layer disposed on a side of the driving circuit layer away from the substrate, wherein the light-emitting device layer is located in the display region and the opening peripheral region;
a first inorganic encapsulation film layer disposed on a side of the light-emitting device layer away from the substrate, wherein the first inorganic encapsulation film layer is located in the display region and the opening peripheral region;
an organic encapsulation film layer disposed on a side of the first inorganic encapsulation film layer away from the substrate, wherein the opening peripheral region further includes a second isolation region, and the organic encapsulation film layer is located in the display region, the second isolation region and the first isolation sub-region; and
a second inorganic encapsulation film layer disposed on a side of the organic encapsulation film layer away from the substrate, wherein the second inorganic encapsulation film layer is located in the display region and the opening peripheral region.

12. The display panel according to claim 11, wherein the driving circuit layer further includes a first gate layer, a second gate layer, a first source-drain metal layer and a second source-drain metal layer; the driving circuit layer further includes a first planarization layer and a second planarization layer;
the at least one insulating layer includes a first insulating layer, a second insulating layer, and an interlayer dielectric layer;
the first gate layer is disposed on a side of the first insulating layer away from the substrate;
the second insulating layer is disposed on a side of the first gate layer away from the substrate;
the second gate layer is disposed on a side of the second insulating layer away from the substrate;
the interlayer dielectric layer is disposed on a side of the second gate layer away from the substrate;
the first source-drain metal layer is disposed on a side of the interlayer dielectric layer away from the substrate;
the first planarization layer is disposed on a side of the first source-drain metal layer away from the substrate;
the second source-drain metal layer is disposed on a side of the first planarization layer away from the substrate;
the second planarization layer is disposed on a side of the second source-drain metal layer away from the substrate;
the display panel further comprises second isolation columns, and the plurality of first isolation columns and the second isolation columns are arranged in a same layer as the second source-drain metal layer.

13. The display panel according to claim 11, wherein a region between the first isolation sub-region and the second isolation sub-region is a second encapsulation dam region;
the second encapsulation dam region is provided therein with at least one second encapsulation dam, the at least one second encapsulation dam surrounds the opening region, and the at least one second encapsulation dam is disposed on a side of the driving circuit layer away from the substrate.

14. The display panel according to claim 13, wherein the opening peripheral region further includes a first encapsulation dam region, the first encapsulation dam region is provided therein with at least one first encapsulation dam, and a thickness of the first encapsulation dam in the first direction is greater than a thickness of the second encapsulation dam in the first direction.

15. The display panel according to claim 13, wherein the opening peripheral region further includes a first encapsulation dam region, and the first encapsulation dam region is provided therein with at least one first encapsulation dam; the driving circuit layer further includes a first planarization layer and a second planarization layer; and the light-emitting device layer includes a pixel defining layer;
the first encapsulation dam includes:
a first portion, wherein the first portion and the first planarization layer are arranged in a same layer;
a second portion, wherein the second portion is disposed on a side of the first portion away from the substrate, and the second portion and the second planarization layer are arranged in a same layer; and
a third portion, wherein the third portion is disposed on a side of the second portion away from the substrate, and the third portion and the pixel defining layer are arranged in a same layer; and
the second encapsulation dam includes a third portion arranged in a same layer as the pixel defining layer.

16. The display panel according to claim 12, wherein a first isolation region of the two first isolation regions is provided therein with a plurality of first patterns and a plurality of second patterns, the plurality of first patterns are located in the first gate layer, and the plurality of second patterns are located in the second gate layer;
each first pattern surrounds the opening region, and each second pattern surrounds the opening region; and
orthographic projections, on the substrate, of the first isolation column, the first pattern, and the second pattern have a common overlapping region.

17. The display panel according to claim 11, further comprising:
an inorganic insulating layer disposed on a side of the second inorganic encapsulation film layer away from the substrate and located in the display region and the opening peripheral region; and
an organic cover layer disposed on a side of the inorganic insulating layer away from the substrate and located in the display region and the opening peripheral region.

18. A method for manufacturing a display panel, comprising:
forming a substrate, wherein the substrate has a display region, at least one opening region and an opening peripheral region located between the opening region and the display region, and the opening peripheral region surrounds the opening region; the substrate has an opening in the opening region; and the opening peripheral region includes a first isolation region, and the first isolation region surrounds the opening region;
forming a driving circuit layer on the substrate, wherein the driving circuit layer includes at least one insulating layer, and the at least one insulating layer is located in the display region and the opening peripheral region;
forming at least one groove on the at least one insulating layer in the first isolation region, wherein the at least one groove surrounds the opening region;
forming a filling layer in the at least one groove, wherein a material of the filling layer is an organic material; and
forming first isolation columns on two sides of each groove in a radial direction of the opening region, wherein the first isolation columns are located in the first isolation region, and the first isolation columns surround the opening region.

19. The method for manufacturing the display panel according to claim 18, wherein the step of forming the at least one groove on the at least one insulating layer in the first isolation region includes:
forming a plurality of grooves in the at least one insulating layer in the first isolation region, wherein the plurality of grooves includes first grooves and second grooves that are arranged alternately in the radial direction of the opening region;
the step of forming the plurality of grooves in the at least one insulating layer in the first isolation region includes:
forming a plurality of third grooves in the at least one insulating layer in the first isolation region, wherein the plurality of third grooves surround the opening region, and the plurality of third grooves are arranged at intervals along the radial direction of the opening region; and among the plurality of third grooves, every other third groove is selected as a target groove; and
forming a fourth groove in each target groove, wherein the fourth groove and the target groove in which the fourth groove is located form a first groove of the first grooves; and among the plurality of third grooves, third grooves that are not selected as target grooves form the second grooves;
the step of forming the filling layer in the at least one groove includes:
forming a first filling layer and a second filling layer in the first groove, and forming a second filling layer in a second groove of the second grooves, including:
forming a first planarization layer on a side of the at least one insulating layer away from the substrate, wherein a portion of the first planarization layer forms a first filling layer in the first groove; and
forming a second planarization layer on a side of the first planarization layer away from the substrate, wherein portions of the second planarization layer form a second filling layer in the first groove and a second filling layer in the second groove.

20. The method for manufacturing a display panel according to claim 18, wherein
the step of forming the substrate includes:
dividing the opening peripheral region into two first isolation regions, wherein the two first isolation regions are respectively a first isolation sub-region and a second isolation sub-region, the first isolation sub-region and the second isolation sub-region are arranged at intervals in the radial direction of the opening region, and the second isolation sub-region is closer to the opening region than the first isolation sub-region; and a region between the first isolation sub-region and the second isolation sub-region is a second encapsulation dam region; and
dividing a region, located between the display region and the first isolation sub-region, of the opening peripheral region into a second isolation region and a first encapsulation dam region, wherein the second isolation region and the first encapsulation dam region surround the opening region, and the first encapsulation dam region is closer to the first isolation region than the second isolation region;
the method for manufacturing the display panel further comprises:
forming a light-emitting device layer on a side of the driving circuit layer away from the substrate, wherein the light-emitting device layer is located in the display region and the opening peripheral region;
forming a first inorganic encapsulation film layer on a side of the light-emitting device layer away from the substrate, wherein the first inorganic encapsulation film layer is located in the display region and the opening peripheral region;
forming an organic encapsulation film layer on a side of the first inorganic encapsulation film layer away from the substrate, wherein the organic encapsulation film layer is located in the display region, the second isolation region and the first isolation sub-region;
forming a second inorganic encapsulation film layer on a side of the organic encapsulation film layer away from the substrate, wherein the second inorganic encapsulation film layer is located in the display region and the opening peripheral region;
forming an inorganic insulating layer on a side of the second inorganic encapsulation film layer away from the substrate, wherein the inorganic insulating layer is located in the display region and the opening peripheral region; and
forming an organic cover layer on a side of the inorganic insulating layer away from the substrate, wherein the organic cover layer is located in the display region and the opening peripheral region.

21. A display device, comprising the display panel according to claim 1.
